(19) United States
(12) Patent Application Publication
(10) Pub. No.: US 2025/0309139 A1
(43) Pub. Date: Oct. 2, 2025

(54) SEMICONDUCTOR PACKAGE AND METHOD

(71) Applicant: Taiwan Semiconductor Manufacturing Co., Ltd., Hsinchu (TW)

(72) Inventors: Shin-Puu Jeng, Hsinchu (TW); Li-Ling Liao, Hsinchu (TW); Ming-Chih Yew, Hsinchu (TW)

(21) Appl. No.: 18/771,081

(22) Filed: Jul. 12, 2024

Related U.S. Application Data
(60) Provisional application No. 63/570,310, filed on Mar. 27, 2024.

(51) Int. Cl. H01L 23/00; H01L 21/48; H01L 23/31; H01L 23/373; H01L 23/498; H01L 23/538; H01L 25/065

(52) U.S. Cl. CPC H01L 23/562; H01L 21/4882; H01L 23/3735; H01L 23/5383; H01L 23/3107; H01L 23/49816; H01L 24/16; H01L 24/32; H01L 24/73; H01L 24/81; H01L 24/83; H01L 24/92; H01L 25/0652; H01L 2224/16227; H01L 2224/32225; H01L 2224/73204; H01L 2224/81935; H01L 2224/83948; H01L 2224/92125

(57) ABSTRACT

A method includes forming a redistribution structure over a carrier, attaching a semiconductor die to the redistribution structure using first conductive connectors, dispensing a first underfill into a first gap between the semiconductor die and the redistribution structure, bonding a substrate to the redistribution structure using second conductive connectors, the substrate being bonded to an opposing side of the redistribution structure as the semiconductor die, and attaching a ring to the substrate, where the ring surrounds the semiconductor die and the first underfill, and where the ring includes a first portion that includes a first material having a first co-efficient of thermal expansion, and second portions that include a second material having a second co-efficient of thermal expansion that is different from the first co-efficient of thermal expansion.

### PRIORITY CLAIM AND CROSS-REFERENCE

This application claims the benefit of U.S. Provisional Application No. 63/570,310, filed on Mar. 27, 2024, which application is hereby incorporated herein by reference.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 6A illustrate cross-sectional views of intermediate stages in the formation of an integrated circuit package according to some embodiments.

FIG. 6B illustrates a cross-sectional view of an integrated circuit die in accordance with some embodiments.

FIGS. 7 through 12B illustrate cross-sectional views and a top-down view of intermediate stages in the formation of the integrated circuit package according to some embodiments.

FIGS. 12C and 12D illustrate cross-sectional views of intermediate stages in the formation of an integrated circuit package according to other embodiments.

FIGS. 13A and 13B illustrate a cross-sectional view and a top-down view of intermediate stages in the formation of an integrated circuit package according to other embodiments.

FIGS. 14A and 14B illustrate a cross-sectional view and a top-down view of intermediate stages in the formation of an integrated circuit package according to other embodiments.

FIGS. 15A and 15B illustrate a cross-sectional view and a top-down view of intermediate stages in the formation of an integrated circuit package according to other embodiments.

FIGS. 16A and 16B illustrate a cross-sectional view and a top-down view of intermediate stages in the formation of an integrated circuit package according to other embodiments.

FIGS. 17A and 17B illustrate a cross-sectional view and a top-down view of intermediate stages in the formation of an integrated circuit package according to other embodiments.

FIGS. 18A and 18B illustrate a cross-sectional view and a top-down view of intermediate stages in the formation of an integrated circuit package according to other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include integrated circuit packages and methods for forming the same. An integrated circuit package includes a package component comprising one or more semiconductor chips bonded to an interposer (also referred to as a redistribution structure), and a package substrate bonded to a side of the interposer opposing the one or more semiconductor chips. A seal adhesive is dispensed on a periphery of the package substrate, and a ring is subsequently placed on the package substrate. The ring makes contact with the package substrate by way of the seal adhesive. The ring may be square-shaped or rectangular-shaped when seen in a top-down view, and may comprise a first portion that includes a first material having a first co-efficient of thermal expansion (CTE). The ring may also comprise second portions that include a second material, wherein each of the second portions is disposed at a corner region of the ring. For example, each second portion of the ring may have an L-shape when seen in a top-down view, and may be embedded in the first portion of the ring at a corresponding corner region of the ring. Specifically, each second portion of the ring may be disposed at an inner corner region of the ring, wherein the inner corner of the ring is also an inner corner of the corresponding L-shape, and wherein the inner corner of the L-shape refers to the juncture where the two arms of the L-shape meet (e.g., to form an angle of 90° between the two arms). The second material may have a second co-efficient of thermal expansion (CTE) that is smaller than the first co-efficient of thermal expansion (CTE). Advantageous features of such embodiments includes allowing the tuning of a total co-efficient of thermal expansion (CTE) of the ring by adjusting for example, the shape, volume, and positions of the second portions of the ring. As a result, the total co-efficient of thermal expansion (CTE) of the ring can be optimized to minimize thermal stresses within the integrated circuit package in order to reduce a risk of warping of the package substrate. In addition, this optimization can also reduce thermal stresses at the interfaces of the integrated circuit package, resulting in a reduced risk of forming cracks or delamination. As a result, package reliability is improved.

Embodiments will now be described with respect to system on chip on wafer (SoCoW) devices in a fan-out package. However, the embodiments described are not intended to limit the embodiments, as the ideas presented may be included in a wide range of embodiments, including any suitable technology generation, all of which are fully intended to be included within the scope.

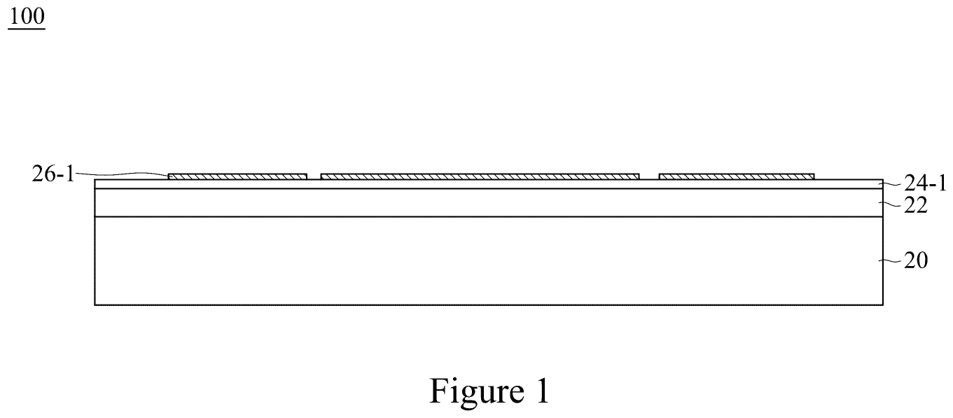

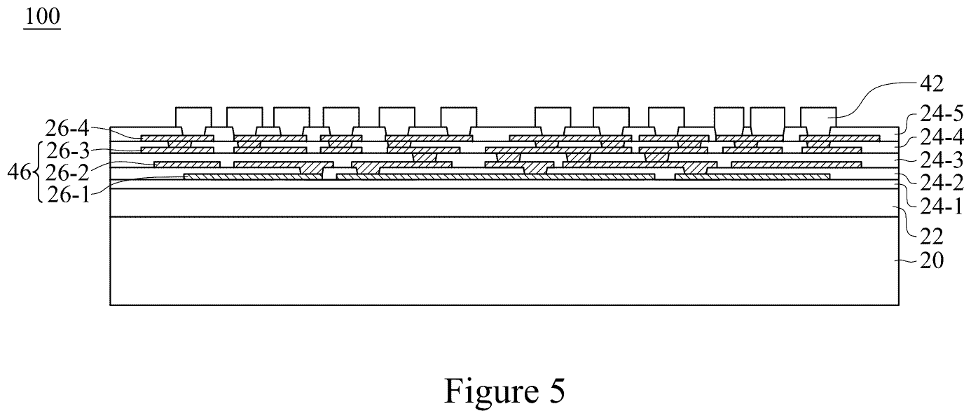

FIGS. 1 through 12B illustrate cross-sectional views and a top-down view of intermediate steps during a process for forming a first package component 100, in accordance with some embodiments. FIGS. 1 through 5 illustrate the formation of a redistribution structure 46 (shown subsequently in FIG. 5). In some embodiments, the redistribution structure 46 may be referred to as an organic interposer. FIG. 1 illustrates a carrier 20 and release film 22 formed on the carrier 20. The carrier 20 may be a glass carrier, a silicon wafer, an organic carrier, or the like. The carrier 20 may have a round top-view shape in accordance with some embodiments. The release film 22 may be formed of a polymer-based material and/or an epoxy-based thermal-release material (such as a Light-To-Heat-Conversion (LTHC) material), which is capable of being decomposed under radiation such as a laser beam, so that the carrier 20 may be de-bonded from the overlying structures that will be formed in subsequent processes. In other embodiments, the release film 22 may be an ultra-violet (UV) glue, which loses its adhesive property when exposed to UV lights. The release film 22 may be dispensed as a liquid and cured, may be a laminate film laminated onto the carrier 20, or the like. The top surface of the release film 22 may be leveled and may have a high degree of planarity.

The redistribution structure 46 (shown subsequently in FIG. 5), includes a plurality of insulating layers 24 and a plurality of RDLs 26 (e.g., conductive lines) that are formed over the release film 22. An insulating layer 24-1, which is one of the insulating layers 24, is formed on the release film 22. In accordance with some embodiments of the present disclosure, the insulating layer 24-1 is formed of a dielectric material such as silicon oxide, silicon nitride, or the like. In an embodiment, the insulating layer 24-1 may comprise an organic material, which may be a polymer. The organic material may also be a photo-sensitive material. For example, the insulating layer 24-1 may be formed of or comprise polyimide, polybenzoxazole (PBO), benzocyclobutene (BCB), or the like. The insulating layer 24-1 may be formed by spin coating, lamination, CVD, the like, or a combination thereof.

A RDL 26-1, which is one of the RDLs 26, is formed on the insulating layer 24-1. The formation of the RDL 26-1 may include forming a metal seed layer (not shown) over the insulating layer 24-1, forming a patterned mask (not shown) such as a photoresist over the metal seed layer, and then performing a metal plating process on the exposed metal seed layer. The patterned mask and the portions of the metal seed layer covered by the patterned mask are then removed, leaving the RDL 26-1 as shown in FIG. 1. In accordance with some embodiments of the present disclosure, the metal seed layer includes a titanium layer and a copper layer over the titanium layer. In an embodiment, the plated metal comprises copper, aluminum, or the like. The metal seed layer may be formed using, for example, Physical Vapor Deposition (PVD) or a like process. The plating may be performed using, for example, a chemical electrical plating process.

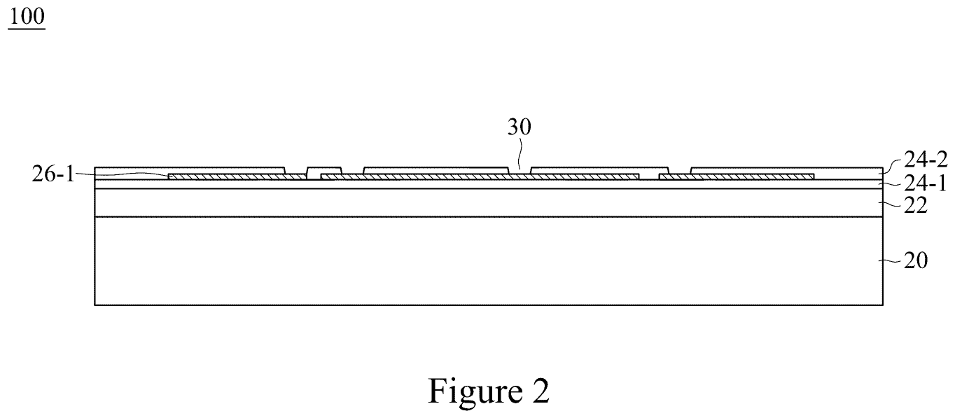

FIGS. 2 through 5 illustrate the formation of additional insulating layers 24 (including insulating layers 24-2, 24-3, 24-4 and 24-5, for example) and additional RDLs 26 (including RDLs 26-2, 26-3 and 26-4, for example). In FIG. 2, the insulating layer 24-2 is first formed on the RDL 26-1. The bottom surface of the insulating layer 24-2 is in contact with top surfaces of the RDL 26-1 and the insulating layer 24-1. The insulating layer 24-2 may be formed of a dielectric material such as silicon oxide, silicon nitride, or the like. In an embodiment, the insulating layer 24-2 may comprise an organic material, which may be a polymer. The organic material may also be a photo-sensitive material. For example, the insulating layer 24-2 may be formed of or comprise polyimide, polybenzoxazole (PBO), benzocyclobutene (BCB), or the like. The insulating layer 24-2 may be formed by spin coating, lamination, CVD, the like, or a combination thereof. The insulating layer 24-2 is then patterned to form via openings (occupied by via portions of subsequently formed RDL 26-2) therein. Hence, some portions of the RDL 26-1 are exposed through the openings in the insulating layer 24-2.

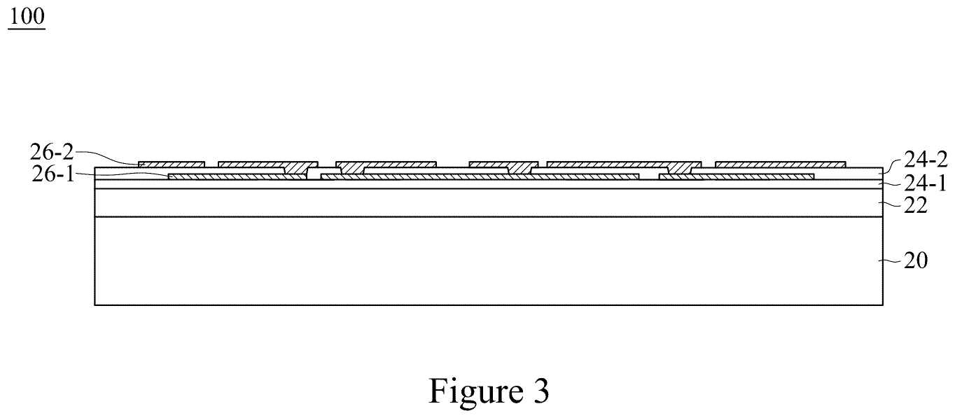

In FIG. 3, the RDL 26-2 is formed on the insulating layer 24-2, wherein the RDL 26-2 is electrically connected to the RDL 26-1. The RDL 26-2 includes via portions extending into the openings in the insulating layer 24-2, and trace portions (metal line portions) over the insulating layer 24-2. In accordance with some embodiments, the formation of the RDL 26-2 may include depositing a blanket metal seed layer extending into the via openings, and forming and patterning a plating mask (such as a photoresist), with openings formed in the plating mask and directly over the via openings. A plating process is then performed to plate a metallic material, which fully fills the via openings, and has some portions higher than a top surface of the insulating layer 24-2. The plating mask is then removed, followed by an etching process to remove the exposed portions of the metal seed layer, which was previously covered by the plating mask. The remaining portions of the metal seed layer and the plated metallic material form the RDL 26-2. The RDL 26-2 includes metal trace portions and via portions (also referred to as vias). The trace portions are over the insulating layer 24-2, and the via portions are in the insulating layer 24-2. Each of the vias may have a tapered profile, with the upper portions wider than the corresponding lower portions. The metal seed layer and the plated material may be formed of the same material or different materials. For example, the metal seed layer may include a titanium layer, and a copper layer over the titanium layer. The plated metallic material of the RDL 26-2 may include a metal or a metal alloy including copper, aluminum, tungsten, or the like, or alloys thereof.

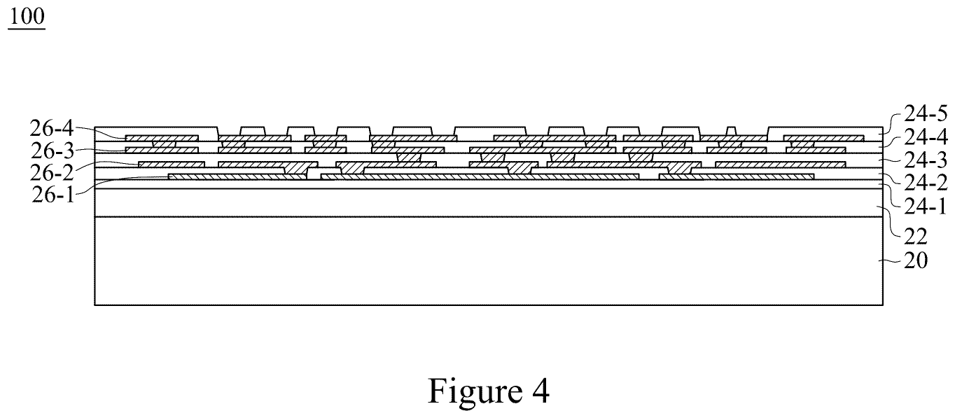

FIG. 4 illustrates that after the formation of the RDL 26-2, there may be more insulating layers and corresponding RDLs formed, with the upper RDLs over and landing on the respective lower RDLs. For example, FIG. 4 illustrates insulating layers 24-3, 24-4 and 24-5, and RDLs 26-3 and 26-4 as an example. It is appreciated that in other embodiments, there may be fewer or more insulating layers and RDLs formed than are shown in FIG. 4. The material of the insulating layers 24-3, 24-4 and 24-5 may be selected from the same group (or different group) of candidate materials as insulating layers 24-1 and 24-2, and the insulating layers 24-3, 24-4 and 24-5 may be formed using similar formation processes. The RDLs 26-3 and 26-4 may also be formed of similar materials, and using similar formation processes, as the RDLs 26-1 and 26-2.

A topmost insulating layer of the insulating layers 24, for example, the insulating layer 24-5 is patterned using acceptable photolithography and etching techniques to form openings in the insulating layer 24-5 that expose a topmost RDL of the RDLs 26, for example, the RDL 26-4. The locations of the openings in insulating layer 24-5 correspond to the locations in which conductive connectors 42 (shown subsequently in FIG. 5) are to be formed for electrical connection of the redistribution structure 46 to other package components in a subsequent step.

In FIG. 5, the conductive connectors 42 may be formed. In an embodiment the conductive connectors 42 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The conductive connectors 42 may include a conductive material such as solder, copper, aluminum, gold, nickel, silver, palladium, tin, the like, or a combination thereof. In some embodiments, the conductive connectors 42 are formed by initially forming a layer of solder through evaporation, electroplating, printing, solder transfer, ball placement, or the like. Once a layer of solder has been formed on the structure, a reflow may be performed in order to shape the material into the desired bump shapes.

In another embodiment, the conductive connectors 42 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In other embodiments, the redistribution structure 46 can be replaced by a semiconductor-comprising interposer (not illustrated in the Figures). The semiconductor-comprising interposer may comprise a bulk semiconductor substrate, SOI substrate, multi-layered semiconductor substrate, or the like. The semiconductor material of the substrate may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor-comprising interposer may comprise a substrate that is doped or undoped. In some embodiments, the semiconductor-comprising interposer will not include active devices therein, although the semiconductor-comprising interposer may include passive devices formed in and/or on a first surface of the substrate.

The semiconductor-comprising interposer may comprise through-vias (TVs) that extend from the first surface of the substrate to a second surface of the substrate. The TVs are also sometimes referred to as through-substrate vias or through-silicon vias when the substrate is a silicon substrate. The interposer may also comprise a redistribution structure over the first surface of the substrate, wherein the redistribution structure is electrically connected to the TVs of the substrate. In some embodiments, the redistribution structure may be formed using one or more methods similar to those described above with respect to the redistribution structure 46.

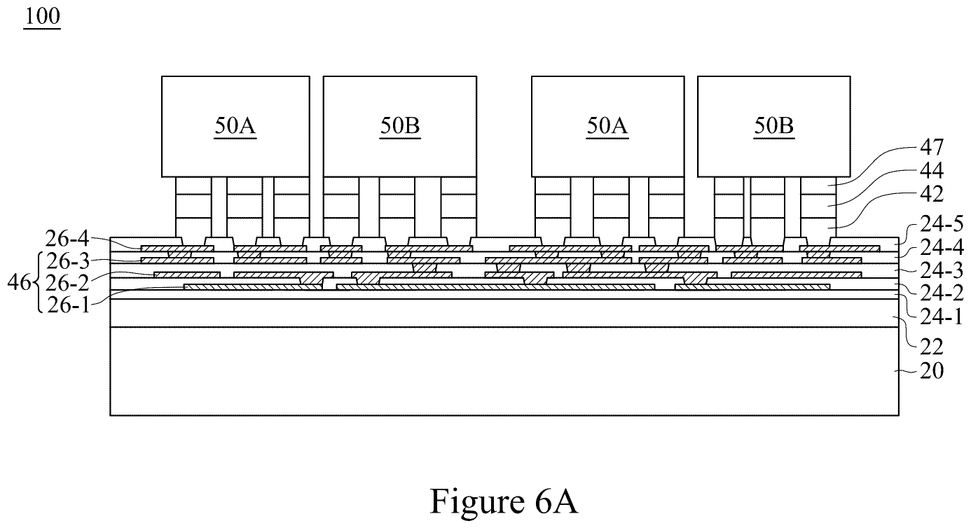

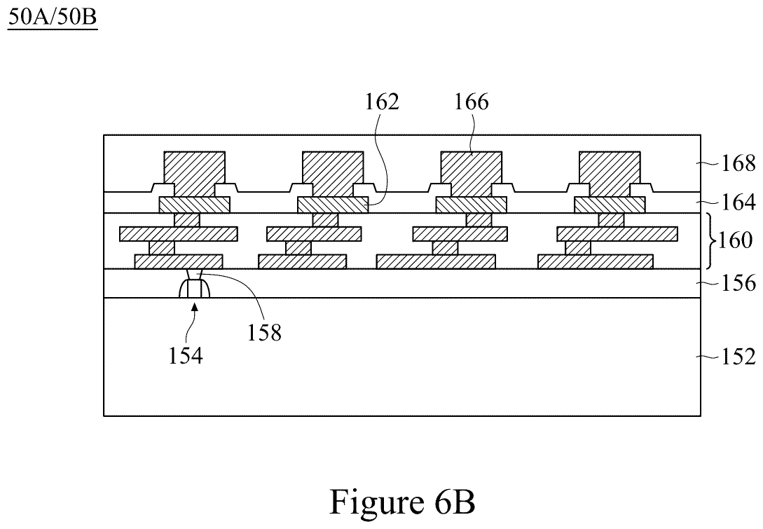

In FIGS. 6A-6B, one or more package components 50A and one or more package components 50B are bonded to the redistribution structure 46. For example, in FIG. 6A, two package components 50A and two package components 50B are shown as being bonded to the redistribution structure 46. Each package component 50A may comprise a semiconductor die. In an embodiment, each package component 50A may comprise a System-on-Chip (SoC) die that includes a plurality of device dies packaged as a system, or the like. The device dies may include logic dies, memory dies, input-output dies, Integrated Passive Devices (IPDs), or the like, or combinations thereof. For example, the logic device dies of each package component 50A may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies of each package component 50A may include Static Random Access Memory (SRAM) dies, Dynamic Random Access Memory (DRAM) dies, or the like. In other embodiments, each package component 50A may comprise an Application Specific Integrated Circuit (ASIC) die.

FIG. 6B illustrates a detailed view of an example package component 50A when the package component 50A is a semiconductor die. The package component 50A may be formed in a wafer, which may include different device regions that are singulated in subsequent steps to form a plurality of integrated circuit dies. The package component 50A may be processed according to applicable manufacturing processes to form integrated circuits. For example, the package component 50A includes a semiconductor substrate 152, such as silicon, doped or undoped, or an active layer of a semiconductor-on-insulator (SOI) substrate. The semiconductor substrate 152 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 152 has an active surface (e.g., the surface facing upwards in FIG. 6B), sometimes called a front side, and an inactive surface (e.g., the surface facing downwards in FIG. 6B), sometimes called a back side.

Devices (represented by a transistor) 154 may be formed at the front surface of the semiconductor substrate 152. The devices 154 may be active devices (e.g., transistors, diodes, etc.), capacitors, resistors, etc. An inter-layer dielectric (ILD) 156 is over the front surface of the semiconductor substrate 152. The ILD 156 surrounds and may cover the devices 154. The ILD 156 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 158 extend through the ILD 156 to electrically and physically couple the devices 154. For example, when the devices 154 are transistors, the conductive plugs 158 may couple the gates and source/drain regions of the transistors. Source/drain region(s) may refer to a source or a drain, individually or collectively dependent upon the context. The conductive plugs 158 may be formed of tungsten, cobalt, nickel, copper, silver, gold, aluminum, the like, or combinations thereof. An interconnect structure 160 is over the ILD 156 and conductive plugs 158. The interconnect structure 160 interconnects the devices 154 to form an integrated circuit. The interconnect structure 160 may be formed by, for example, metallization patterns in dielectric layers on the ILD 156. The metallization patterns include metal lines and vias formed in one or more low-k dielectric layers. The metallization patterns of the interconnect structure 160 are electrically coupled to the devices 154 by the conductive plugs 158.

The package component 50A further includes pads 162, such as aluminum pads, to which external connections are made. The pads 162 are on the active side of the package component 50A, such as in and/or on the interconnect structure 160. One or more passivation films 164 are on the package component 50A, such as on portions of the interconnect structure 160 and pads 162. Openings extend through the passivation films 164 to the pads 162. Die connectors 166, such as conductive pillars (for example, formed of a metal such as copper), extend through the openings in the passivation films 164 and are physically and electrically coupled to respective ones of the pads 162. The die connectors 166 may be formed by, for example, plating, or the like. The die connectors 166 electrically couple the respective integrated circuits of the package component 50A.

Optionally, solder regions (e.g., solder balls or solder bumps) may be disposed on the pads 162. The solder balls may be used to perform chip probe (CP) testing on the package component 50A. CP testing may be performed on the package component 50A to ascertain whether the package component 50A is a known good die (KGD). Thus, only package components 50A, which are KGDs, undergo subsequent processing and are packaged, and dies, which fail the CP testing, are not packaged. After testing, the solder regions may be removed in subsequent processing steps.

A dielectric layer 168 may (or may not) be on the active side of the package component 50A, such as on the passivation films 164 and the die connectors 166. The dielectric layer 168 laterally encapsulates the die connectors 166, and the dielectric layer 168 is laterally coterminous with the package component 50A. Initially, the dielectric layer 168 may bury the die connectors 166, such that the topmost surface of the dielectric layer 168 is above the topmost surfaces of the die connectors 166. In some embodiments where solder regions are disposed on the die connectors 166, the dielectric layer 168 may bury the solder regions as well. Alternatively, the solder regions may be removed prior to forming the dielectric layer 168.

The dielectric layer 168 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 168 may be formed, for example, by spin coating, lamination, chemical vapor deposition (CVD), or the like. In some embodiments, the die connectors 166 are exposed through the dielectric layer 168 during formation of the package component 50A. In some embodiments, the die connectors 166 remain buried and are exposed during a subsequent process for packaging the package component 50A. Exposing the die connectors 166 may remove any solder regions that may be present on the die connectors 166.

In an embodiment, conductive connectors 47 (which may also be referred to subsequently as UBMS and are shown in FIG. 6A) are formed for external connection to the package component 50A. The conductive connectors 47 have bump portions on and extending along the major surface of the dielectric layer 168, and may have via portions extending through the dielectric layer 168 to electrically couple to the interconnect structure 160 and the pads 162. As a result, the conductive connectors 47 are electrically coupled to the package components 50A. The conductive connectors 47 may be formed of the same material as the metallization patterns of the interconnect structure 160.

In some embodiments, the package component 50A is a stacked device that includes multiple semiconductor substrates 152. For example, the package component 50A may be a memory device such as a hybrid memory cube (HMC) module, a high bandwidth memory (HBM) module, or the like that includes multiple memory dies. In such embodiments, the package component 50A includes multiple semiconductor substrates 152 interconnected by through-substrate vias (TSVs). Each of the semiconductor substrates 152 may (or may not) have an interconnect structure 160.

Each package component 50B may be a semiconductor die similar to the package component 50A that was described above with respect to FIG. 6B. Each of the package components 50B may include system on chip dies, logic dies, DRAM dies, SRAM dies, central processing unit dies, I/O dies, combinations of these, or the like. For example, each package component 50B may comprise a memory die such as a DRAM die (e.g., a high bandwidth memory (HBM) die), or the like. The memory dies may be discrete memory dies, or may be in the form of a die stack that includes a plurality of stacked memory dies. In some embodiments, the package components 50B are bare dies (sometimes referred to as bare chips), and are semiconductor dies that have not be encapsulated or otherwise include fan-out redistribution structures.

Referring further to FIG. 6A, in some embodiments, the package components 50A and the package components 50B are bonded to the redistribution structure 46 using conductive connectors 44, such as solder, or the like. For example, solder may be placed on conductive connectors 47 of the package components 50A and the package components 50B or the conductive connectors 42, and the package components 50A and the package components 50B may be placed on the conductive connectors 42 and a reflow process performed. The conductive connectors 44 may also include non-solder metal pillars, or metal pillars and solder caps over the non-solder metal pillars, which may also be formed through plating. Other types of bonding, such as metal-to-metal direct bonding, hybrid bonding (including both of dielectric-to-dielectric bonding and metal-to-metal direct bonding), or the like may also be used. In an embodiment, after the package components 50A and the package components 50B are bonded to the redistribution structure 46, top surfaces of the package components 50A may be level with top surfaces of the package components 50B. In other embodiments, after the package components 50A and the package components 50B are bonded to the redistribution structure 46, the top surfaces of the package components 50A may be at a different level with the top surfaces of the package components 50B.

It is appreciated that while FIG. 6A illustrates two package components 50A and two package components 50B coupled to the redistribution structure 46, other numbers of the package components 50A and the package components 50B may be coupled to the redistribution structure 46.

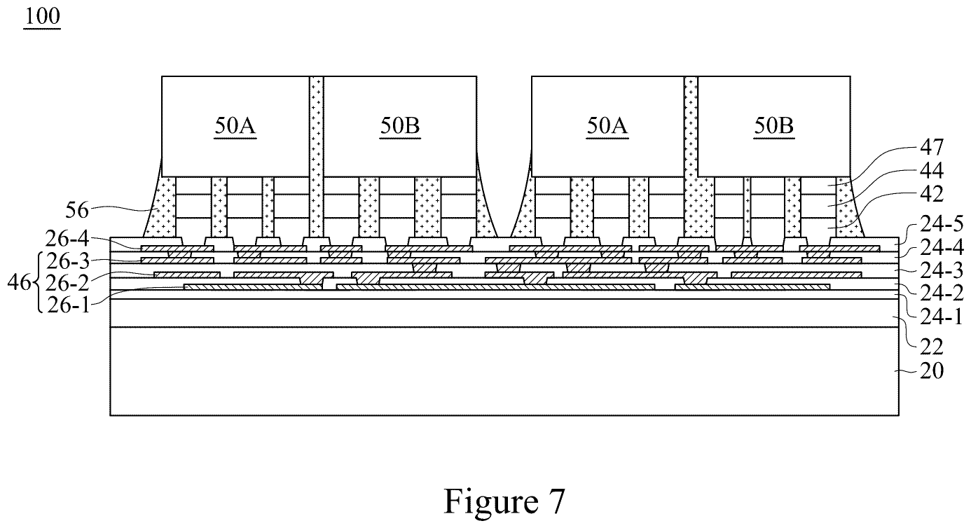

In FIG. 7, an underfill 56 is formed between package components 50A and the redistribution structure 46, as well as between the package components 50B and the redistribution structure 46. The underfill 56 may also fill a gap between each package component 50A and an adjacent package component 50B. In some embodiments, the underfill 56 includes a base material, such as an epoxy, and filler particles in the epoxy, and may be deposited by a capillary flow process after the package components 50A and the package components 50B are attached or may be formed by a suitable deposition method before the package components 50A and the package components 50B are attached. Some example base materials include epoxy-amine, epoxy anhydride, epoxy phenol, or the like, or the combinations thereof. The filler particles may be formed of a dielectric material, and may include silica, alumina, boron nitride, or the like, which may be in the form of spherical particles. The underfill 56 may undergo a curing process after being formed. FIG. 7 shows an embodiment where the underfill 56 has a flat top surface level with top surfaces of the package components 50A and the package components 50B. In some embodiments, the top surface of the underfill 56 may not be flat and may be lower than the top surfaces of package components 50A and the package components 50B.

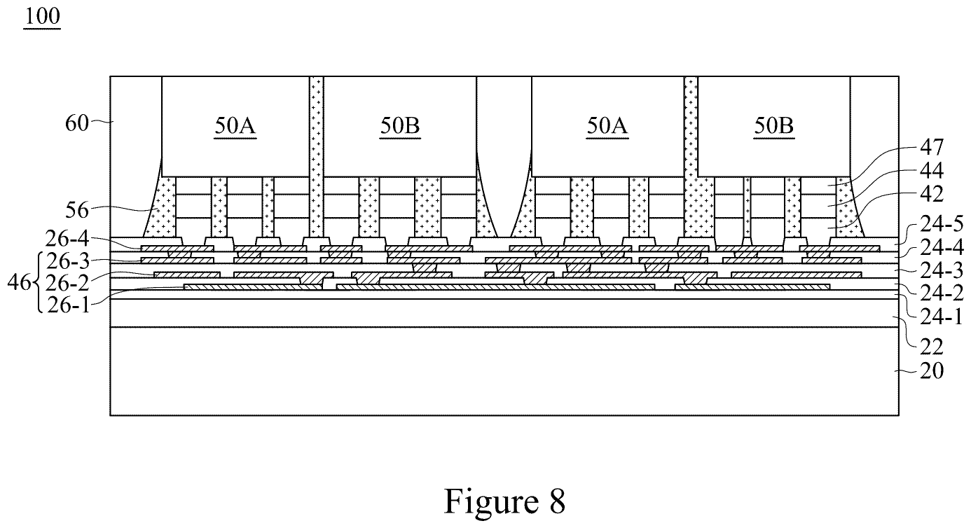

In FIG. 8, package components 50A, and the package components 50B are encapsulated in an encapsulant 60. The encapsulant 60 may be applied by compression molding, transfer molding, or the like, and may be formed over the first package component 100, such that package components 50A and package components 50B are buried or covered. The encapsulant 60 may be applied in liquid or semi-liquid form and subsequently cured, for example, at a temperature in a range between about 120° C. and about 180° C. The encapsulant 60 may include a molding compound, a molding underfill, an epoxy, and/or a resin. The molding compound may include a base material, which may be a polymer, a resin, an epoxy, or the like, and filler particles in the base material. The filler particles may be dielectric particles of SiO₂, Al₂O₃, silica, or the like, and may have spherical shapes. Also, the spherical filler particles may have the same or different diameters. The encapsulant 60 may further surround the underfill 56. There may be a distinguishable interface between the underfill 56 and the encapsulant 60.

In a subsequent process, a planarization process such as a Chemical Mechanical Polish (CMP) process or a mechanical grinding process is performed to polish the encapsulant 60. Top surfaces of the package components 50A and the package components 50B may be exposed as a result of the planarization process.

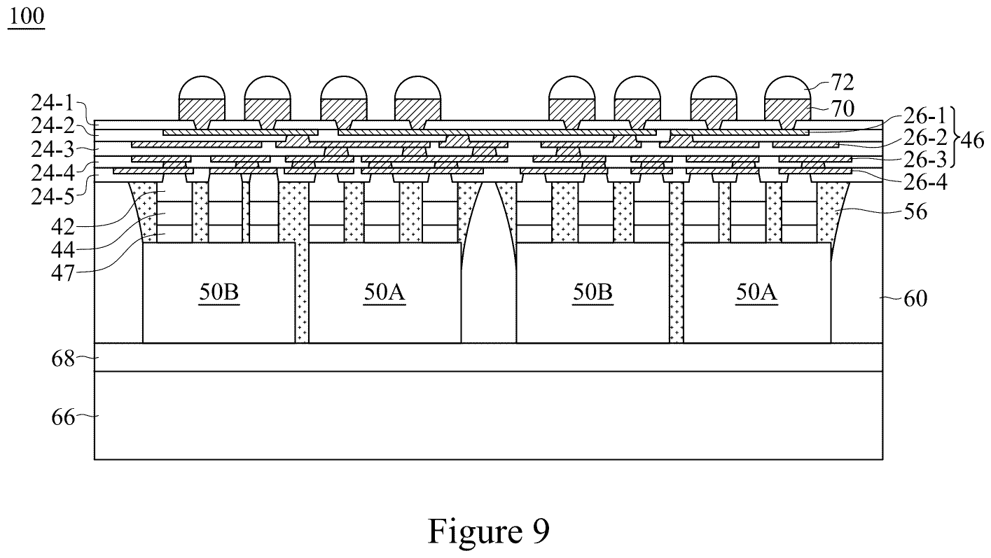

FIG. 9 illustrates a carrier swap and the formation of conductive connectors on a side of the redistribution structure 46. A carrier 66 is attached to surfaces of the encapsulant 60 and exposed surfaces of the package components 50A and the package components 50B using release film 68. The carrier 20, shown in FIG. 8, is detached from the first package component 100. The detaching process may include projecting a light beam, such as a laser beam, or UV light, on the release film 22 shown in FIG. 8, and the light beam penetrates through the carrier 20, which may be transparent. As a result of the light-exposure, such as the laser scanning, the release film 22 is decomposed by the heat of the light beam, and the carrier 20 may be lifted off from the release film 22. The corresponding process is also referred to as the de-bonding.

As a result of the de-bonding process, the insulating layer 24-1 is exposed. UBMs 70 and conductive connectors 72 are formed on the redistribution structure 46. The formation process may include patterning the insulating layer 24-1 to form openings that expose the RDL 26-1, and forming UBMs 70, which extend into the openings in the insulating layer 24-1. The UBMs 70 may be formed by first depositing a conductive metal using any suitable method, for example, sputtering, evaporation, PECVD, or the like. Suitable photolithographic masking and etching process are then used to remove portions of the conductive metal, and the remaining portions of the conductive metal form the UBMs 70. UBMs 70 may be formed of or comprise nickel, copper, titanium, or multi-layers thereof. In some embodiments, each of UBMs 70 includes a titanium layer and a copper layer over the titanium layer.

Conductive connectors 72 are formed on the UBMs 70. In an embodiment the conductive connectors 72 may be controlled collapse chip connection (C4) bumps, or the like. In some embodiments, the conductive connectors 72 are formed by initially forming a layer of solder on the exposed portions of the UBMs 70 through evaporation, electroplating, printing, solder transfer, ball placement, or the like, and thereafter reflowing the layer of solder. The conductive connectors 72 are therefore solder regions. The conductive connectors 72 may also include non-solder metal pillars, or metal pillars and solder caps over the non-solder metal pillars, which may also be formed through plating.

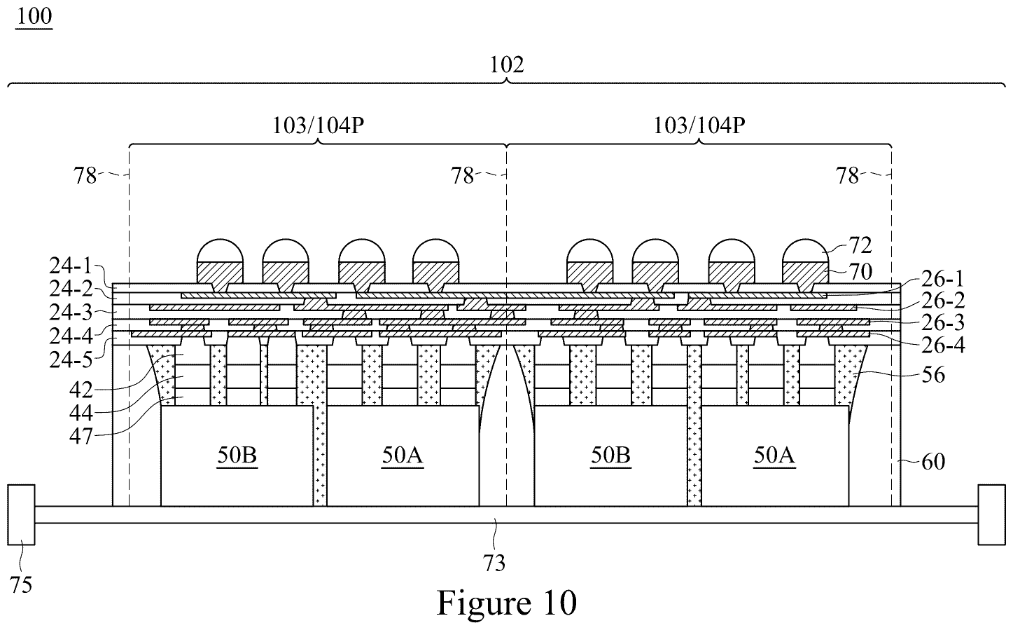

In FIG. 10, the carrier 66 is detached from the first package component 100 to leave a remaining wafer structure 102. The detaching process may include projecting a light beam, such as a laser beam, or UV light, on the release film 68 shown in FIG. 9, and the light beam penetrates through the carrier 66, which may be transparent. As a result of the light-exposure, such as the laser scanning, the release film 68 is decomposed by the heat of the light beam, and carrier 66 may be lifted off from the release film 68. The wafer structure 102 is then placed on tape 73, which is supported by a frame 75.

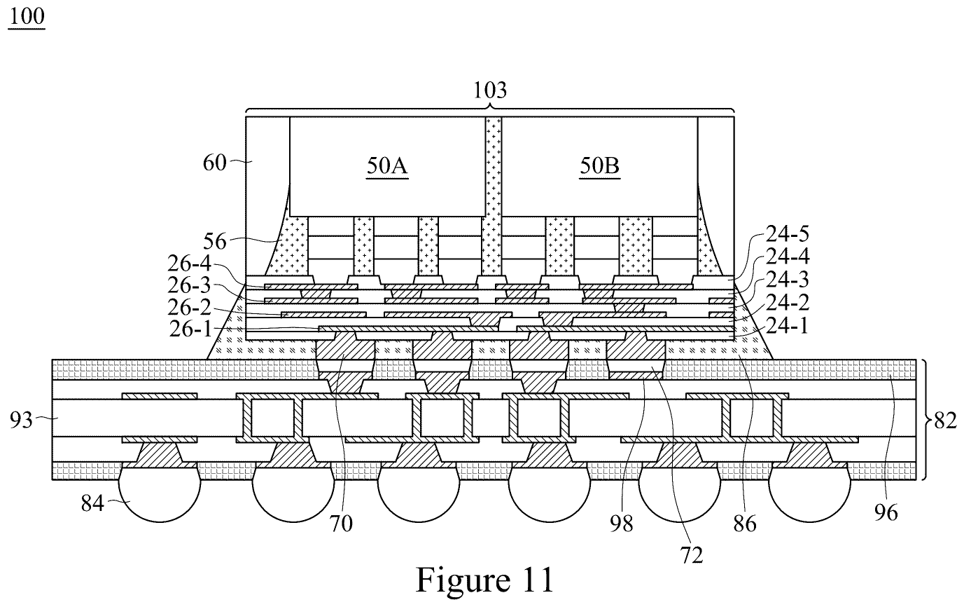

In FIG. 11, the wafer structure 102 on the tape 73 (shown previously in FIG. 10) is then singulated between adjacent regions 104P along scribe lines 78 (shown previously in FIG. 10), so that the wafer structure 102 is separated into discrete package structures 103.

Referring further to FIG. 11, each discrete package structure 103 is then bonded to a package component 82. The bonding is via the conductive connectors 72, which may include solder regions. The package component 82 may be or may comprise an interposer, a package, a core substrate, a coreless substrate, a printed circuit board, or the like. FIG. 11 shows an embodiment where package component 82 includes a substrate core 93 and bond pads 98 over the substrate core 93. The substrate core 93 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 93 may be an SOI substrate. Generally, an SOI substrate includes a layer of a semiconductor material such as epitaxial silicon, germanium, silicon germanium, SOI, SGOI, or combinations thereof. The substrate core 93 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 93.

The substrate core 93 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 93 may also include metallization layers and vias (not shown), with the bond pads 98 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 93 is substantially free of active and passive devices.

In some embodiments, the conductive connectors 72 are reflowed to attach the discrete package structure 103 to the bond pads 98. The conductive connectors 72 electrically and/or physically couple the package component 82, including metallization layers in the substrate core 93, to the discrete package structure 103. In some embodiments, a solder resist 96 is formed on the substrate core 93. The conductive connectors 72 may be disposed in openings in the solder resist 96 to be electrically and mechanically coupled to the bond pads 98. The solder resist 96 may be used to protect areas of the substrate core 93 from external damage.

The conductive connectors 72 may have an epoxy flux (not shown) formed thereon before they are reflowed with at least some of the epoxy portion of the epoxy flux remaining after the discrete package structure 103 is attached to the package component 82. This remaining epoxy portion may act as an underfill to reduce stress and protect the joints resulting from reflowing the conductive connectors 72. An underfill 86 may be dispensed into the gap between the redistribution structure 46 and the package component 82. The underfill 86 may also be disposed on sidewalls of the redistribution structure 46 and the discrete package structure 103. In accordance with some embodiments, underfill 86 includes a base material and filler particles mixed in the base material. The base material may include a resin, an epoxy, and/or a polymer. Some example base materials include epoxy-amine, epoxy anhydride, epoxy phenol, or the like, or the combinations thereof. The filler particles are formed of a dielectric material, and may include silica, alumina, boron nitride, or the like, which may be in the form of spherical particles. Underfill 86 may be dispensed in a flowable form, and is then cured.

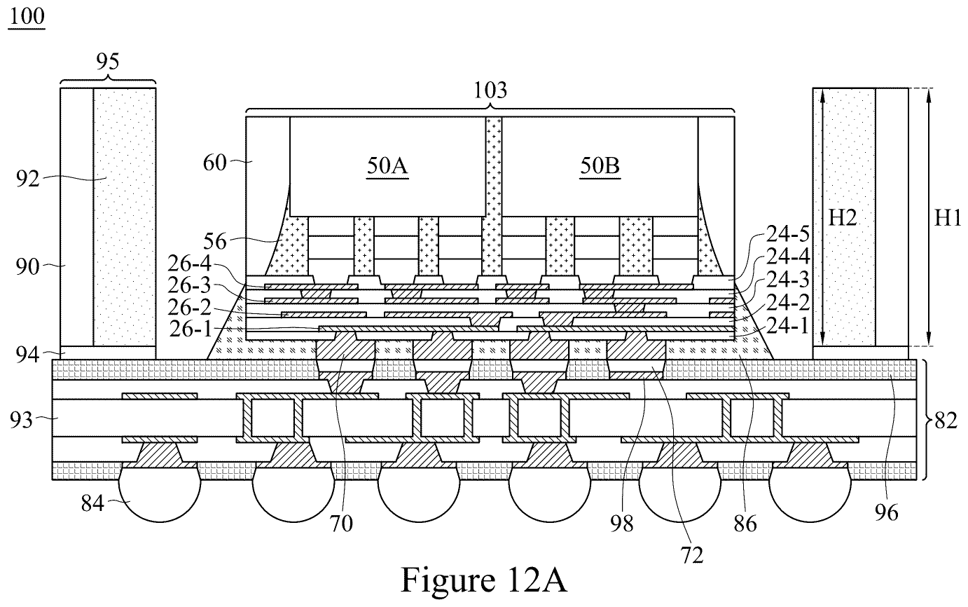

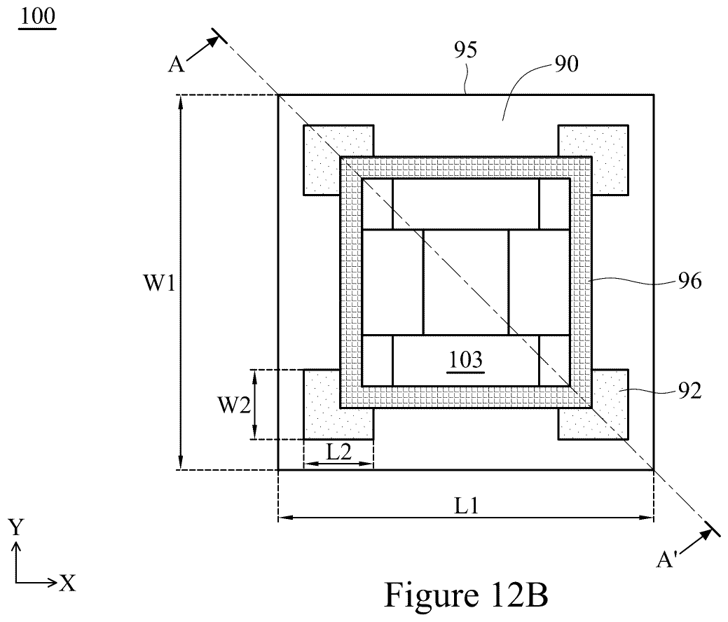

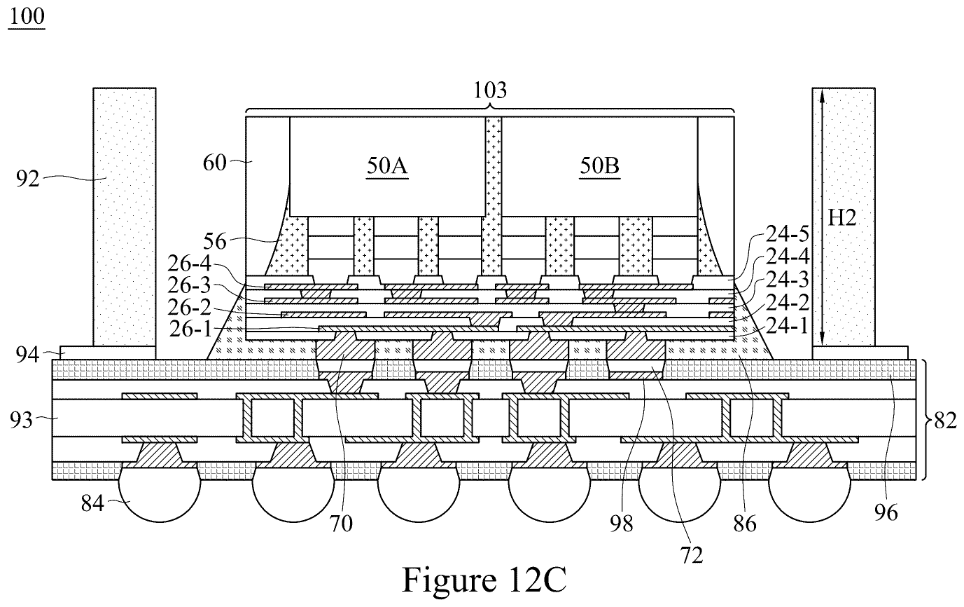

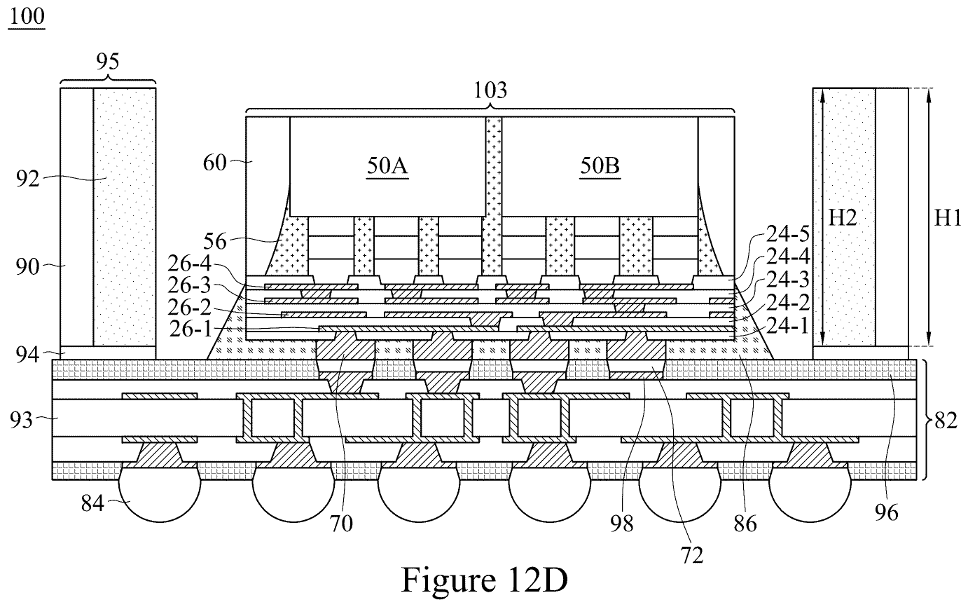

In FIGS. 12A-12B, an adhesive material 94 is dispensed on the package component 82, and a ring 95 is coupled to the package component 82. FIG. 12A illustrates a cross-sectional view of the first package component 100 along a line A-A′ shown in FIG. 12B. The adhesive material 94 may comprise any material suitable for sealing a component such as a ring onto the package component 82, such as epoxies, urethane, polyurethane, silicone elastomers, and the like. The adhesive material 94 may be dispensed to an outer portion or a periphery of the package component 82, such that the adhesive material 94 is between the discrete package structure 103 and the edges of the package component 82. A ring 95 is then attached to the package component 82 using the adhesive material 94, in accordance with some embodiments. The ring 95 may be used to dissipate heat from the first package component 100 and to provide additional support to the package component 82 during subsequent manufacturing processes and usage. The ring 95 may also be used to control and minimize thermal stresses within the first package component 100 in order to reduce a risk of warping of the package component 82. The ring 95 may be placed on the package component 82 so that the ring 95 surrounds and encircles the package components 50A, the package components 50B, the underfill 56, the underfill 86 and the encapsulant 60. After the ring 95 is placed on the package component 82, a curing process may be performed to solidify the adhesive material 94 and strengthen the coupling between the ring 95 and the package component 82. In an embodiment the ring 95 may comprise a ring structure that includes a lid.

The ring 95 may be square-shaped or rectangular-shaped when seen in a top-down view, and may comprise a first portion of the ring 90 that includes a first material having a first co-efficient of thermal expansion (CTE). The ring 95 may also comprise second portions of the ring 92 that include a second material, wherein each second portion of the ring 92 is disposed at a corresponding corner region of the ring 95. For example, each second portion of the ring 92 may have an L-shape when seen in a top-down view, and be embedded in the first portion of the ring 90 at a corresponding corner region of the ring 95. Specifically, each second portion of the ring 92 may be disposed at a corresponding inner corner region of the ring 95, wherein an inner corner of the L-shape of the second portion of the ring 92 also serves as the inner corner of the ring 95, and wherein the inner corner of the L-shape refers to the juncture where the two arms of the L-shape meet, forming an angle of 90° between the two arms. The second material may have a second co-efficient of thermal expansion (CTE) that is smaller than the first co-efficient of thermal expansion (CTE). In an embodiment, the first material may comprise copper, or the like, and the second material may comprise aluminum, or the like. In an embodiment the first CTE may be in a range from 16-20 ppm/° C. and the second CTE may be in a range from 8-14 ppm/° C. In an embodiment, the ring 95 is formed prior to attaching the ring 95 to the package component 82. For example, the second portions of the ring 92 are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact, prior to attaching the ring 95 to the package component 82. In an embodiment, a height H1 of the first portion of the ring 90 may be the same as a height H2 of the second portions of the ring 92. In an embodiment, the height H1 of the first portion of the ring 90 may be different from the height H2 of the second portions of the ring 92.

FIG. 12B illustrates a top-down view of the first package component 100 shown in FIG. 12A. The FIG. 12B illustrates a first axis (e.g., the x-axes) and a second axes (e.g., the y-axes), wherein the first axis and the second axis are orthogonal to each other. The first package component 100 may comprise four second portions of the ring 92 that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view, wherein four sidewalls of the second portion of the ring 92 are in physical contact with the first portion of the ring 90. In addition, each second portion of the ring 92 may be disposed at a corresponding inner corner region of the ring 95, wherein an inner corner of the L-shape of the second portion of the ring 92 also serves as the inner corner of the ring 95, and wherein the inner corner of the L-shape refers to the juncture where the two arms of the L-shape meet, forming an angle of 90° between the two arms.

Advantages can be achieved as a result of a method for the formation of the first package component 100 that comprises the ring 95 being attached to the package component 82, the ring 95 being square-shaped or rectangular-shaped when seen in a top-down view. The ring 95 comprises the first portion of a ring 90 that includes the first material (e.g., copper, or the like) having the first CTE that is in a range from 16-20 ppm/° C. The ring 95 also comprises second portions of the ring 92, wherein each second portion of the ring 92 is embedded in the first portion of the ring 90 at a corresponding corner region of the ring 95, and wherein each second portion of the ring 92 and the first portion of the ring 90 are in physical contact. Each second portion of the ring 92 may have an L-shape when seen in a top-down view. The second portions of the ring 92 comprise the second material (e.g., aluminum, or the like) having the second CTE that is in a range from 8-14 ppm/° C., and the second CTE is lower than the first CTE. These advantages include allowing the tuning of a total co-efficient of thermal expansion (CTE) of the ring 95. As a result, the total co-efficient of thermal expansion (CTE) of the ring 95 can be optimized to minimize thermal stresses within the first package component 100 in order to reduce a risk of warping of the package component 82. In addition, this optimization can also reduce thermal stresses at the interfaces of the first package component 100, resulting in a reduced risk of forming cracks or delamination (e.g., between the redistribution structure 46 and the discrete package structure 103. As a result, package reliability is improved. For example, the ring 95 comprising only the first material having the first CTE may result in a total CTE of the ring 95 being too high, and may result in significant thermal mismatch stresses within the first package component 100 during operation, which increases a risk of delamination or cracking within the first package component 100. As a result, package reliability may be reduced. In addition, the ring 95 comprising only the second material having the second CTE may result in the total CTE of the ring 95 being too low, and would result in an increased risk of warpage of the package component 82. As a result, mechanical stresses may be induced in the first package component 100 that increase a risk of delamination or cracking within the first package component 100. Therefore, package reliability will also be negatively affected.

In an embodiment, the ring 95 may have a width W1 that is measured in a direction parallel to the second axes (e.g., the y-axes), and each second portion of the ring 92 may have a width W2 that is measured in a direction parallel to the second axes (e.g., the y-axes). In an embodiment, the ring 95 may have a length L1 that is measured in a direction parallel to the first axes (e.g., the x-axes), and each second portion of the ring 92 may have a length L2 that is measured in a direction parallel to the first axes (e.g., the x-axes). In an embodiment, the length L2 and the width W2 may be the same. In an embodiment, the length L2 and the width W2 are different. In an embodiment, a ratio of the width W2 to the width W1 may be in a range from 0.1 to 0.4. In an embodiment, a ratio of the length L2 to the length L1 may be in a range from 0.1 to 0.4. In an embodiment, the length L2 and the width W2 may be greater than 1 mm.

Advantages can be achieved by having the ratio of the width W2 of each second portion of the ring 92 to the width W1 of the ring 95 being in the range from 0.1 to 0.4. Further advantages can also be achieved by having the ratio of the length L2 of each second portion of the ring 92 to the length L1 of the ring 95 being in the range from 0.1 to 0.4. These advantages include allowing the tuning and optimization of a total co-efficient of thermal expansion (CTE) of the ring 95 in order to minimize thermal stresses within the first package component 100 in order to reduce a risk of warping of the package component 82. In addition, this optimization can also reduce thermal stresses at the interfaces of the first package component 100, resulting in a reduced risk of forming cracks or delamination. As a result, package reliability is improved. For example, a ratio of the width W2 of each second portion of the ring 92 to the width W1 of the ring 95 being smaller than 0.1, or a ratio of the length L2 of each second portion of the ring 92 to the length L1 of the ring 95 being smaller than 0.1 may result in significant thermal mismatch stresses (as a result of a total CTE of the ring 95 being too high) within the first package component 100 during operation, which increases a risk of delamination (e.g., between the redistribution structure 46 and the discrete package structure 103) or cracking within the first package component 100. Conversely, a ratio of the width W2 of each second portion of the ring 92 to the width W1 of the ring 95 being greater than 0.4, or a ratio of the length L2 of each second portion of the ring 92 to the length L1 of the ring 95 being greater than 0.4 would result in an increased risk of warpage of the package component 82. As a result, mechanical stresses may be induced in the first package component 100 leading to an increased risk of delamination or cracking within the first package component 100. Therefore, package reliability will be negatively affected.

Advantages can be achieved by having the length L2 and the width W2 of each second portion of the ring 92 be greater than 1 mm. These advantages include allowing the second portion of the ring 92 to have a sufficient surface area at a bottom surface of the second portion of the ring 92 that can be used to securely attach to the package component 82 using the adhesive material 94. For example, the length L2 and/or the width W2 being smaller than 1 mm may result in an increased risk of the second portion of the ring 92 being detached from the package component 82 as a result of the smaller surface area available that is insufficient to securely attach to the package component 82. As a result, package reliability may be degraded.

FIGS. 12C-12D illustrate the first package component 100 in accordance with an alternative embodiment. Unless specified otherwise, like reference numerals in this embodiment (and subsequently discussed embodiments) represent like components in the embodiment shown in FIGS. 1 through 12B formed by like processes. Accordingly, the process steps and applicable materials may not be repeated herein. The initial steps of this embodiment are essentially the same as shown in FIGS. 1A through 11.

The embodiment of FIGS. 12C-12D are different from the embodiment of FIGS. 12A-12B in that in the embodiment of FIGS. 12C-12D, the first portion of the ring 90 and the second portions of the ring 92 are not combined together to form the ring 95 prior to attaching the first portion of the ring 90 and the second portions of the ring 92 to the package component 82. In FIG. 12C, the adhesive material 94 is dispensed on the package component 82 in a similar manner as was described previously in FIG. 12A. After the adhesive material 94 is dispensed on the package component 82, the second portions of the ring 92 are then attached to the package component 82 using the adhesive material 94, in accordance with some embodiments. The second portions of the ring 92 are attached in positions such that each second portion of the ring 92 will be disposed at a corresponding corner region of the ring 95 when the first portion of the ring 90 is subsequently attached to the package component 82 as described in FIG. 12D.

In FIG. 12D, after the second portions of the ring 92 are attached to the first package component 100, the first portion of the ring 90 is attached to the package component 82 using the adhesive material 94, such that the first portion of the ring 90 and the second portions of the ring 92 are in physical contact and combine to form the ring 95. After the first portion of the ring 90 is placed on the package component 82, a curing process may be performed to solidify the adhesive material 94 and strengthen the coupling between the ring 95 and the package component 82.

In other embodiments, after the adhesive material 94 is dispensed on the package component 82 as described previously in FIG. 12A, the first portion of the ring 90 is attached to the package component 82 using the adhesive material 94. After the first portion of the ring 90 is attached to the package component 82, the second portions of the ring 92 are attached to the first package component 100 using the adhesive material 94 such that the first portion of the ring 90 and the second portions of the ring 92 are in physical contact and combine to form the ring 95. After the second portions of the ring 92 are placed on the package component 82, a curing process may be performed to solidify the adhesive material 94 and strengthen the coupling between the ring 95 and the package component 82.

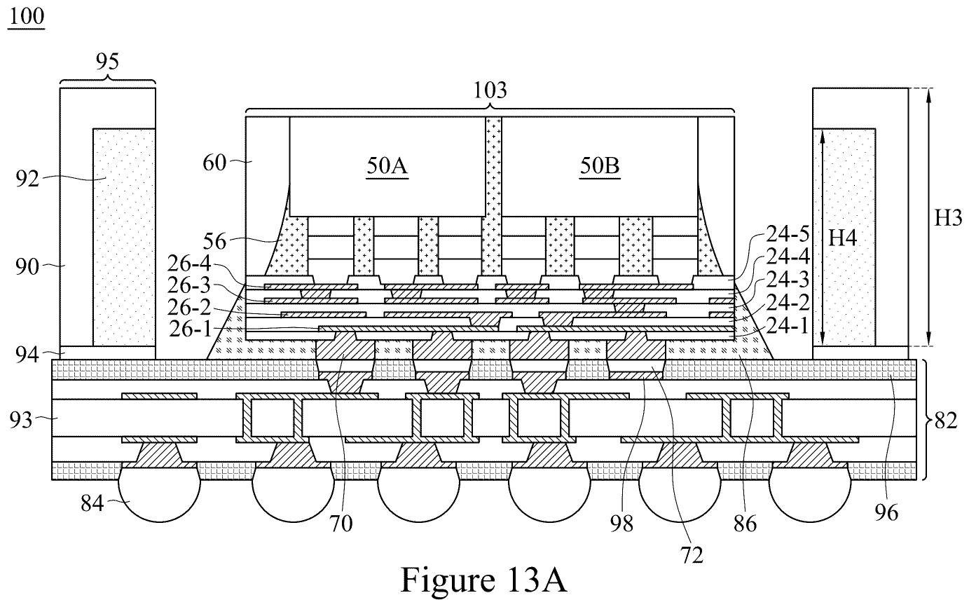

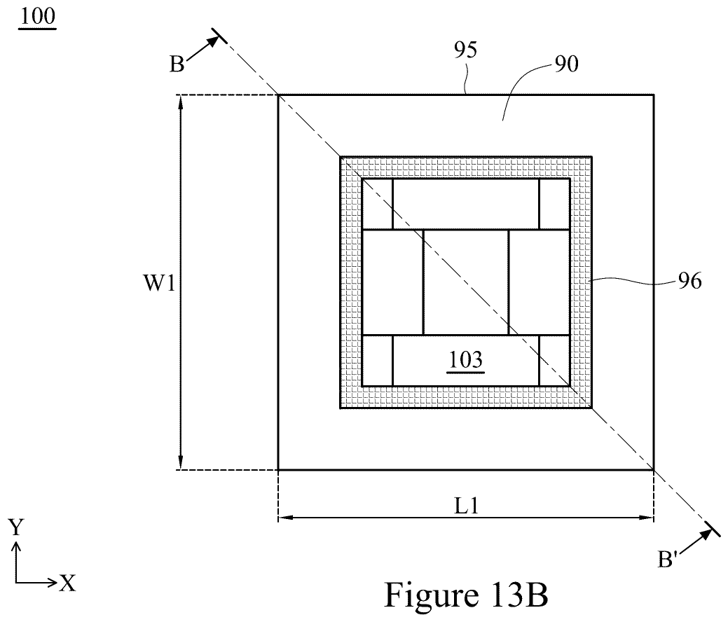

FIGS. 13A-13B illustrate the first package component 100 in accordance with an alternative embodiment. Unless specified otherwise, like reference numerals in this embodiment (and subsequently discussed embodiments) represent like components in the embodiment shown in FIGS. 1 through 12D formed by like processes. Accordingly, the process steps and applicable materials may not be repeated herein.

FIG. 13A illustrates a cross-sectional view of the first package component 100 along a line B-B′ shown in FIG. 13B. FIG. 13B illustrates a top-down view of the first package component 100 shown in FIG. 13A. In the embodiment of FIGS. 13A-13B, the first package component 100 may comprise four second portions of the ring 92 that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view, wherein four sidewalls of the second portion of the ring 92 are in physical contact with the first portion of the ring 90. Both the first portion of the ring 90 and the second portions of the ring 92 are attached to the package component 82 using the adhesive material 94. In addition, the first portion of the ring 90 may also extend over and overlap the second portions of the ring 92, such that a top surface of each second portion of the ring 92 is in physical contact with the first portion of the ring 90. In an embodiment, a height H3 of the first portion of the ring 90 may be different from the height H4 of the second portions of the ring 92. In an embodiment, the height H3 is greater than the height H4.

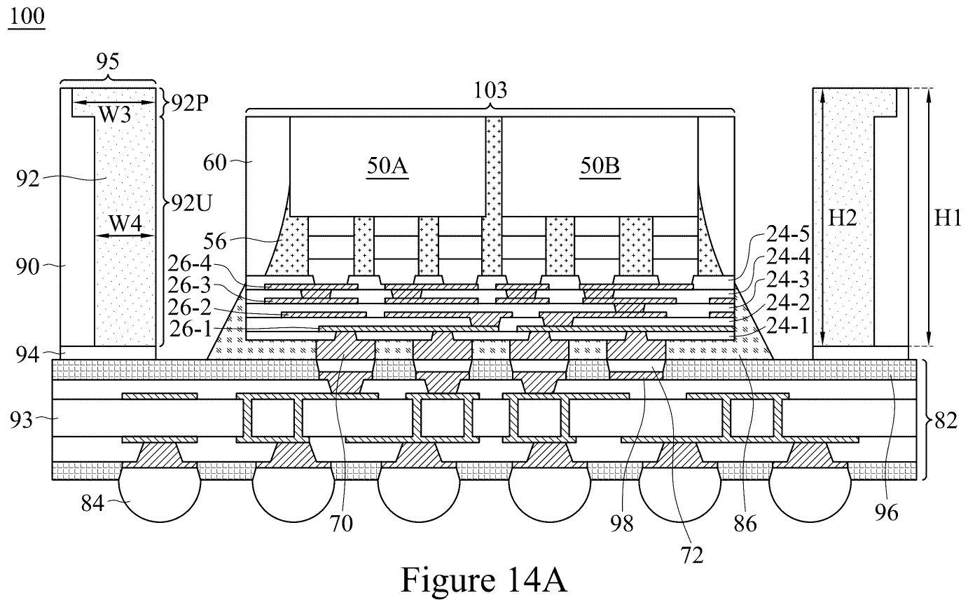

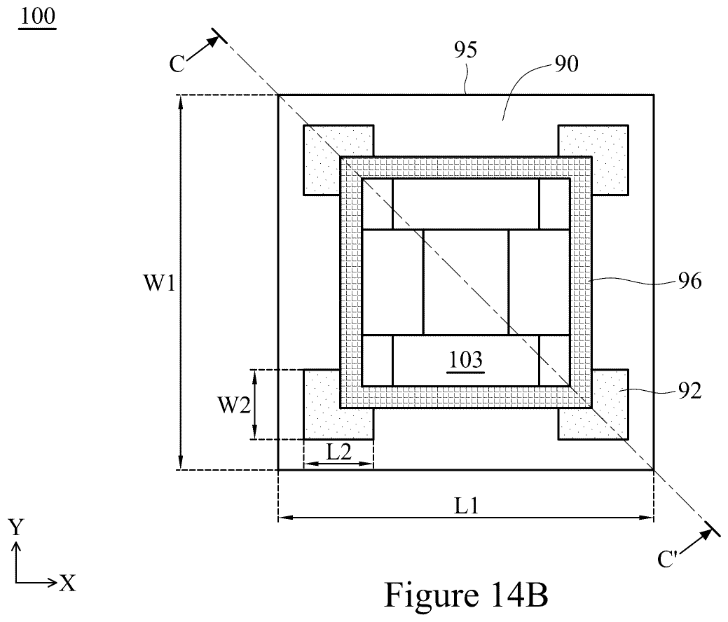

FIGS. 14A-14B illustrate the first package component 100 in accordance with an alternative embodiment. Unless specified otherwise, like reference numerals in this embodiment (and subsequently discussed embodiments) represent like components in the embodiment shown in FIGS. 1 through 13B formed by like processes. Accordingly, the process steps and applicable materials may not be repeated herein.

FIG. 14A illustrates a cross-sectional view of the first package component 100 along a line C-C′ shown in FIG. 14B. FIG. 14B illustrates a top-down view of the first package component 100 shown in FIG. 14A. In the embodiment of FIGS. 14A-14B, the first package component 100 may comprise four second portions of the ring 92 that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view. Both the first portion of the ring 90 and the second portions of the ring 92 are attached to the package component 82 using the adhesive material 94. Each second portion of the ring 92 may have a protruding portion 92P, and a non-protruding portion 92U, wherein the protruding portion 92P extends further away in a lateral direction from an adjacent sidewall of the discrete package structure 103 than the non-protruding portion 92U. In an embodiment, the protruding portion may have a width W3, and the non-protruding portion 92U may have a width W4, wherein the width W3 is greater than the width W4. In an embodiment, the protruding portion 92P is a top portion of the second portion of the ring 92, and the non-protruding portion 92U is a bottom portion of the second portion of the ring 92. In other embodiments, the protruding portion 92P may be disposed at any point along the height H2 of the second portion of the ring 92. For example, the protruding portion 92P may be a bottom portion of the second portion of the ring 92, and the non-protruding portion 92U may be a top portion of the second portion of the ring 92. In other embodiments, the protruding portion 92P may be disposed between two non-protruding portions 92U, wherein a first non-protruding portion 92U is disposed above the protruding portion 92P, and a second non-protruding portion 92U is disposed below the protruding portion 92P.

Advantages can be achieved as a result of a method for the formation of the first package component 100 that comprises the ring 95 being attached to the package component 82, the ring 95 being square-shaped or rectangular-shaped when seen in a top-down view. The ring 95 comprises a first portion of a ring 90 that includes the first material (e.g., copper, or the like) having the first CTE that is in a range from 16-20 ppm/° C. The ring 95 also comprises second portions of the ring 92, wherein each second portion of the ring 92 is embedded in the first portion of the ring 90 at a corresponding corner region of the ring 95, and wherein each second portion of the ring 92 and the first portion of the ring 90 are in physical contact. Each second portion of the ring 92 may have an L-shape when seen in a top-down view. The second portions of the ring 92 comprise the second material (e.g., aluminum, or the like) having the second CTE that is in a range from 8-14 ppm/° C., and the second CTE is lower than the first CTE. In addition, each second portion of the ring 92 may have one or more protruding portions 92P, and one or more non-protruding portion 92U, wherein the protruding portion 92P extends further away in a lateral direction from an adjacent sidewall of the discrete package structure 103 than the non-protruding portion 92U. In an embodiment, the protruding portion may have the width W3, and the non-protruding portion 92U may have the width W4, wherein the width W3 is greater than the width W4. These advantages include allowing the tuning of a total co-efficient of thermal expansion (CTE) of the ring 95 by modifying the width W3 of the protruding portion 92P and the width W4 of the non-protruding portion 92U (e.g., to modify the volume of each second portion of the ring 92). As a result, the total co-efficient of thermal expansion (CTE) of the ring 95 can be optimized to minimize thermal stresses within the first package component 100 in order to reduce a risk of warping of the package component 82. In addition, this optimization can also reduce thermal stresses at the interfaces of the first package component 100, resulting in a reduced risk of forming cracks or delamination (e.g., between the redistribution structure 46 and the discrete package structure 103. As a result, package reliability is improved.

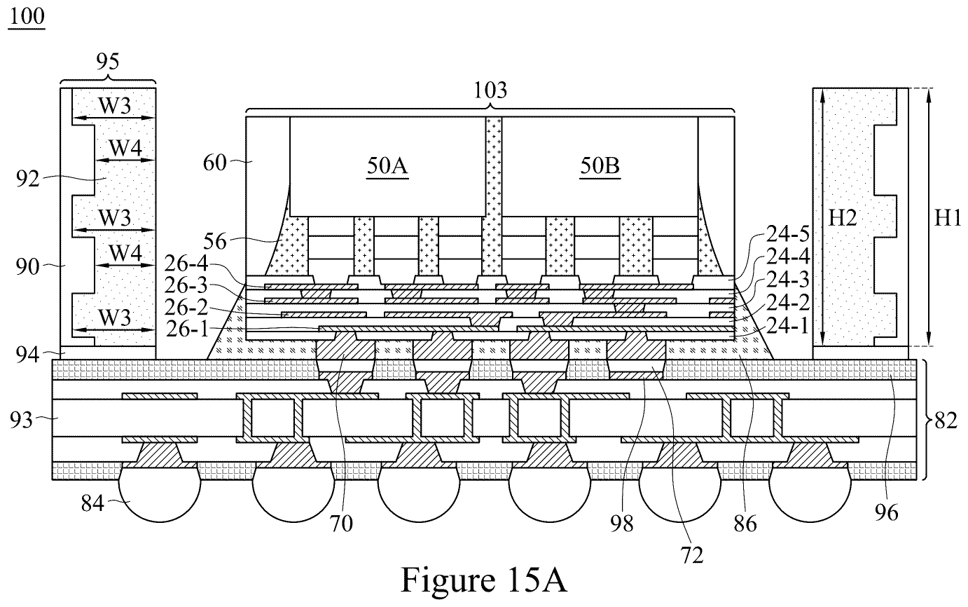

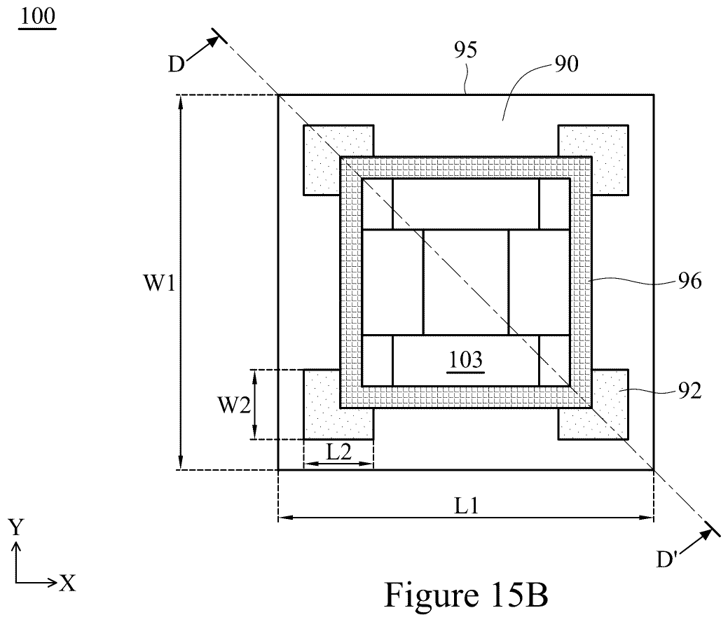

FIGS. 15A-15B illustrate the first package component 100 in accordance with an alternative embodiment. Unless specified otherwise, like reference numerals in this embodiment (and subsequently discussed embodiments) represent like components in the embodiment shown in FIGS. 1 through 14B formed by like processes. Accordingly, the process steps and applicable materials may not be repeated herein.

FIG. 15A illustrates a cross-sectional view of the first package component 100 along a line D-D′ shown in FIG. 15B. FIG. 15B illustrates a top-down view of the first package component 100 shown in FIG. 15A. In the embodiment of FIGS. 15A-15B, the first package component 100 may comprise four second portions of the ring 92 that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view. Both the first portion of the ring 90 and the second portions of the ring 92 are attached to the package component 82 using the adhesive material 94. Each second portion of the ring 92 may have more than one protruding portions 92P, and may have more than one non-protruding portions 92U, wherein each protruding portion 92P extends further away from an adjacent sidewall of the discrete package structure 103 than the non-protruding portions 92U. In an embodiment, the protruding portions 92P and the non-protruding portions 92U may be arranged in an alternating manner.

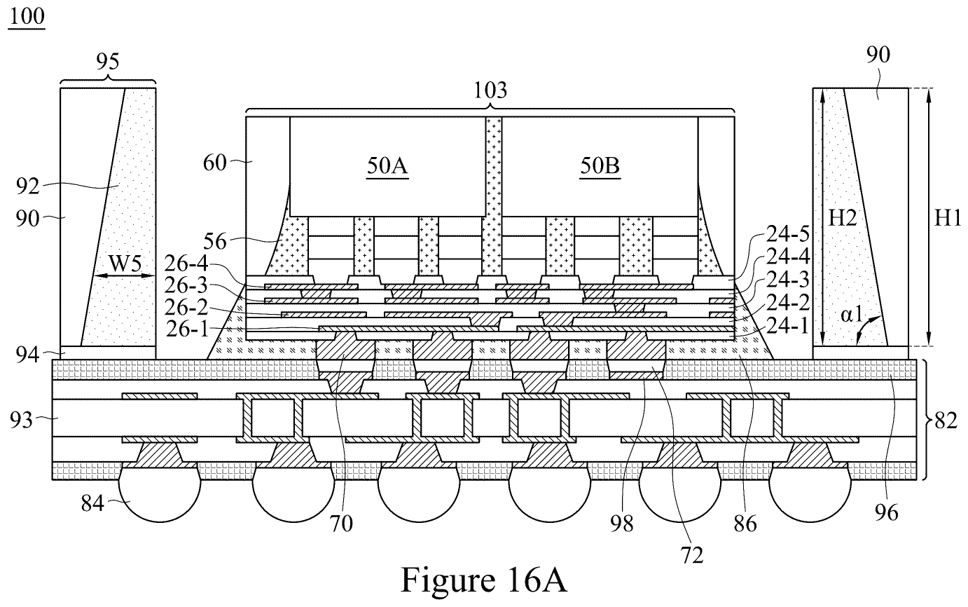

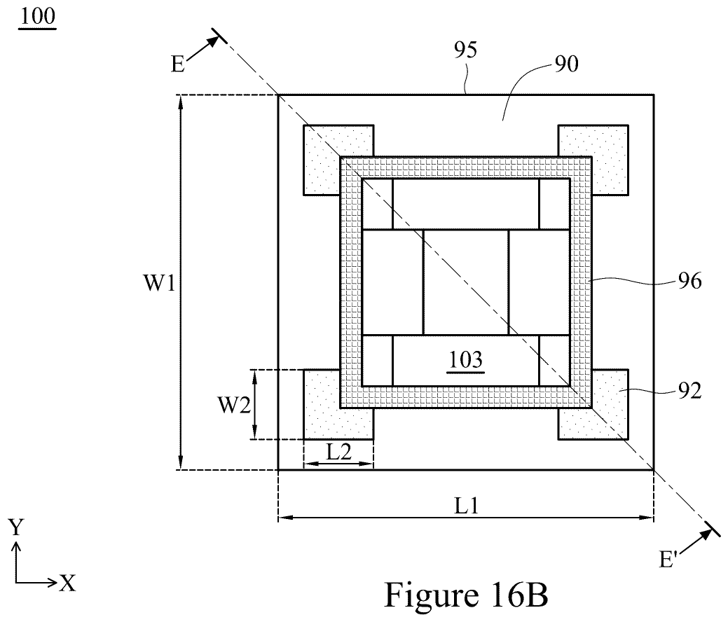

FIGS. 16A-16B illustrate the first package component 100 in accordance with an alternative embodiment. Unless specified otherwise, like reference numerals in this embodiment (and subsequently discussed embodiments) represent like components in the embodiment shown in FIGS. 1 through 15B formed by like processes. Accordingly, the process steps and applicable materials may not be repeated herein.

FIG. 16A illustrates a cross-sectional view of the first package component 100 along a line E-E′ shown in FIG. 16B. FIG. 16B illustrates a top-down view of the first package component 100 shown in FIG. 16A. In the embodiment of FIGS. 16A-16B, the first package component 100 may comprise four second portions of the ring 92 that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view. Both the first portion of the ring 90 and the second portions of the ring 92 are attached to the package component 82 using the adhesive material 94. Each second portion of the ring 92 may have one or more sloping sidewalls, such that interfaces between the first portion of the ring 90 and the second portion of the ring 92 may be inclined at an angle α1. In an embodiment, a width W5 of each second portion of the ring 92 decreases in a direction moving from a bottom surface of the second portion of the ring 92 towards a top surface of the second portion of the ring 92.

Advantages can be achieved as a result of a method for the formation of the first package component 100 that comprises the ring 95 being attached to the package component 82, the ring 95 being square-shaped or rectangular-shaped when seen in a top-down view. The ring 95 comprises a first portion of a ring 90 that includes the first material (e.g., copper, or the like) having the first CTE that is in a range from 16-20 ppm/° C. The ring 95 also comprises second portions of the ring 92, wherein each second portion of the ring 92 is embedded in the first portion of the ring 90 at a corresponding corner region of the ring 95, and wherein each second portion of the ring 92 and the first portion of the ring 90 are in physical contact. Each second portion of the ring 92 may have an L-shape when seen in a top-down view. The second portions of the ring 92 comprise the second material (e.g., aluminum, or the like) having the second CTE that is in a range from 8-14 ppm/° C., and the second CTE is lower than the first CTE. In addition, each second portion of the ring 92 may have one or more sloping sidewalls, such that interfaces between the first portion of the ring 90 and the second portion of the ring 92 may be inclined at the angle α1. In an embodiment, the width W5 of each second portion of the ring 92 decreases in a direction moving from a bottom surface of the second portion of the ring 92 towards a top surface of the second portion of the ring 92. These advantages include allowing the tuning of a total co-efficient of thermal expansion (CTE) of the ring 95 by modifying the angle α1 of inclination of the interfaces between the first portion of the ring 90 and the second portion of the ring 92 (e.g., to modify the volume of each second portion of the ring 92). As a result, the total co-efficient of thermal expansion (CTE) of the ring 95 can be optimized to minimize thermal stresses within the first package component 100 in order to reduce a risk of warping of the package component 82. In addition, this optimization can also reduce thermal stresses at the interfaces of the first package component 100, resulting in a reduced risk of forming cracks or delamination (e.g., between the redistribution structure 46 and the discrete package structure 103. As a result, package reliability is improved.

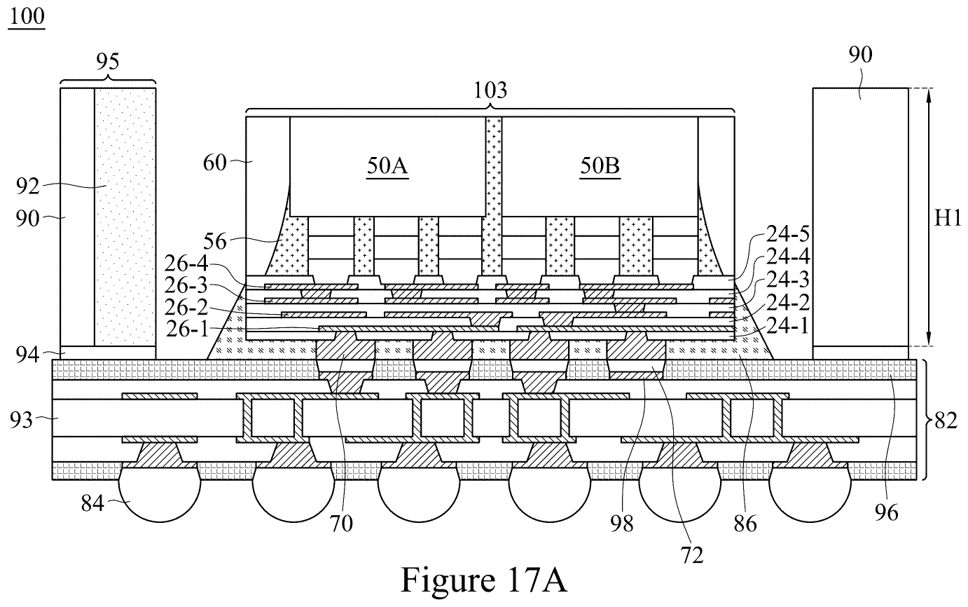

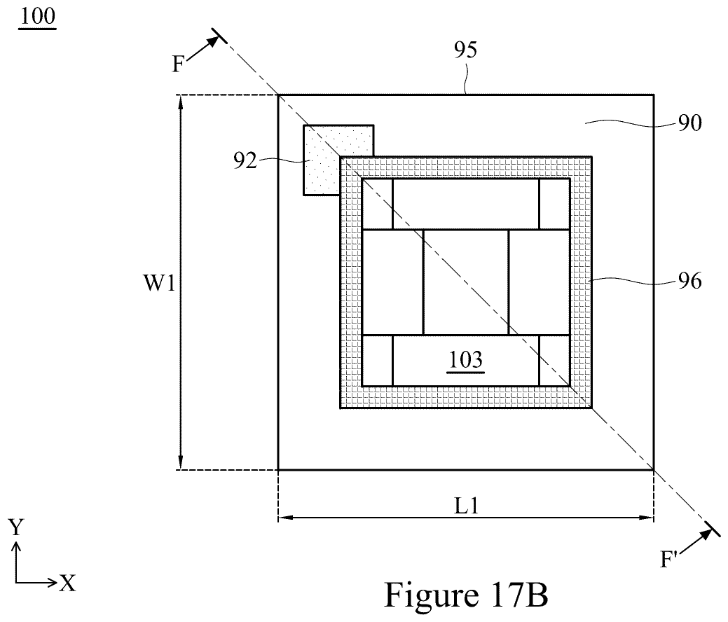

FIGS. 17A-17B illustrate the first package component 100 in accordance with an alternative embodiment. Unless specified otherwise, like reference numerals in this embodiment (and subsequently discussed embodiments) represent like components in the embodiment shown in FIGS. 1 through 16B formed by like processes. Accordingly, the process steps and applicable materials may not be repeated herein.

FIG. 17A illustrates a cross-sectional view of the first package component 100 along a line F-F′ shown in FIG. 17B. FIG. 17B illustrates a top-down view of the first package component 100 shown in FIG. 17A. In the embodiment of FIGS. 17A-17B, the first package component 100 may comprise one or more second portions of the ring 92 (e.g., up to four second portions of the ring 92) that are combined with the first portion of the ring 90 (e.g., by embedding each second portion of the ring 92 in the first portion of the ring 90 at a corresponding corner region of the ring 95) such that each second portion of the ring 92 and the first portion of the ring 90 are in physical contact. Each second portion of the ring 92 may have an L-shape when seen in a top-down view. Both the first portion of the ring 90 and the one or more second portions of the ring 92 are attached to the package component 82 using the adhesive material 94.

In an embodiment, the ring 95 may comprise at least one corner region (and up to three corner regions) that does not have a second portion of the ring 92 embedded within the corner region of the ring 95. For example, the embodiment of FIGS. 17A-17B shows the first package component 100 having only one second portion of the ring 92 that is combined with the first portion of the ring 90 (e.g., by embedding the second portion of the ring 92 in the first portion of the ring 90 at a first corner region of the ring 95). The ring 95 shown in FIGS. 17A-17B therefore has three corner regions that comprise only the first material of the first portion of the ring 90, and the ring 95 does not have a second portion of the ring 92 embedded within any of these three corner regions. The inner corners of each of these three corner regions therefore comprise the first material of the first portion of the ring 90, and these three corner regions are part of the first portion of the ring 90.

Advantages can be achieved as a result of a method for the formation of the first package component 100 that comprises the ring 95 being attached to the package component 82, the ring 95 being square-shaped or rectangular-shaped when seen in a top-down view. The ring 95 comprises a first portion of a ring 90 that includes the first material (e.g., copper, or the like) having the first CTE that is in a range from 16-20 ppm/° C. The ring 95 also comprises one or more second portions of the ring 92, wherein each second portion of the ring 92 is embedded in the first portion of the ring 90 at a corresponding corner region of the ring 95, and wherein each second portion of the ring 92 and the first portion of the ring 90 are in physical contact. Each second portion of the ring 92 may have an L-shape when seen in a top-down view. The second portions of the ring 92 comprise the second material (e.g., aluminum, or the like) having the second CTE that is in a range from 8-14 ppm/° C., and the second CTE is lower than the first CTE. In addition, at least one corner region of the ring 95 (and up to three corner regions) does not have a second portion of the ring 92 embedded within the corner region of the ring 95. These advantages include allowing the local tuning of co-efficients of thermal expansion (CTE) of different regions of the ring 95 by modifying the positions and the number of the second portions of the ring 92 that are embedded in the ring 95. The co-efficients of thermal expansion (CTE) of the different regions of the ring 95 can therefore be optimized to minimize thermal stresses within the first package component 100 in order to reduce a risk of warping of the package component 82. In addition, this optimization can also reduce thermal stresses at the interfaces of the first package component 100, resulting in a reduced risk of forming cracks or delamination (e.g., between the redistribution structure 46 and the discrete package structure 103. As a result, package reliability is improved.

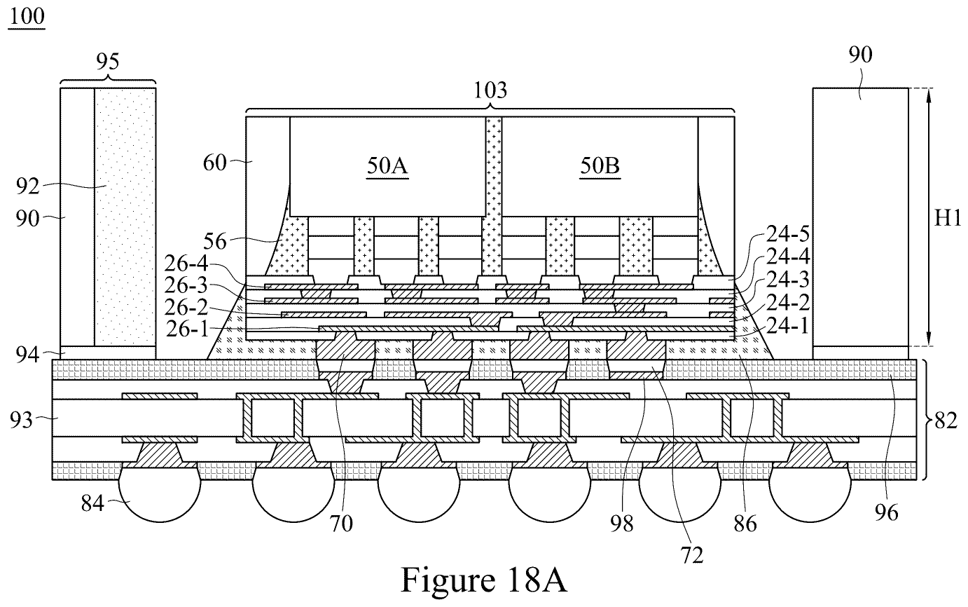

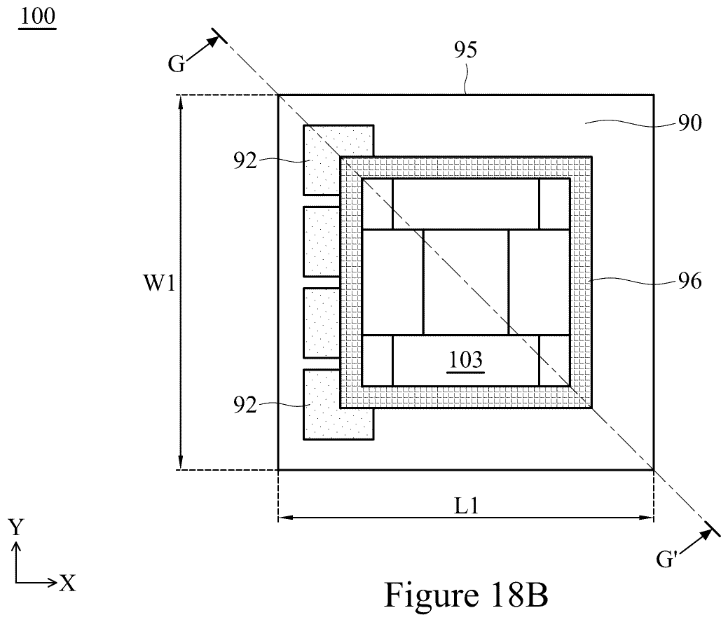

FIGS. 18A-18B illustrate the first package component 100 in accordance with an alternative embodiment. Unless specified otherwise, like reference numerals in this embodiment (and subsequently discussed embodiments) represent like components in the embodiment shown in FIGS. 1 through 17B formed by like processes. Accordingly, the process steps and applicable materials may not be repeated herein.

FIG. 18A illustrates a cross-sectional view of the first package component 100 along a line G-G′ shown in FIG. 18B. FIG. 18B illustrates a top-down view of the first package component 100 shown in FIG. 18A. In the embodiment of FIGS. 18A-18B, the first package component 100 may comprise one or more second portions of the ring 92 that are combined with the first portion of the ring 90 such that each second portion of the ring 92 and the first portion of the ring 90 are in physical contact. Each second portion of the ring 92 may have an L-shape, a square-shape, or a rectangular-shape when seen in a top-down view. Both the first portion of the ring 90 and the one or more second portions of the ring 92 are attached to the package component 82 using the adhesive material 94. Each second portion of the ring 92 may be either embedded in the first portion of the ring 90 at a corresponding corner region of the ring 95, or may be embedded in the first portion of the ring 90 along any point along the length L1 or the width W1 of the ring 95, such that a sidewall of the second portion of the ring 92 also serves as an inner edge of the ring 95.

In an embodiment, the second portions of the ring 92 may be embedded in one or more sides of the ring 95. For example, the FIGS. 18A-18B show that the second portions of the ring 92 are only embedded in one side of the ring 95, and the remaining three sides of the ring 95 do not have any second portions of the ring 92 embedded within them. In an embodiment, any number of second portions of the ring 92 may be embedded within any number of sides (e.g., up to four sides) of the ring 90.

The embodiments of the present disclosure have some advantageous features. The embodiments include the formation of an integrated circuit package that includes a package component comprising one or more semiconductor chips bonded to an interposer (also referred to as a redistribution structure), and a package substrate bonded to a side of the interposer opposing the one or more semiconductor chips. A seal adhesive is dispensed on a periphery of the package substrate, and a ring is subsequently placed on the package substrate. The ring makes contact with the package substrate by way of the seal adhesive. The ring may be square-shaped or rectangular-shaped when seen in a top-down view, and may comprise a first portion that includes a first material having a first co-efficient of thermal expansion (CTE). The ring may also comprise second portions that include a second material, wherein each of the second portions is disposed at a corner region of the ring. For example, each second portion of the ring may have an L-shape when seen in a top-down view, and may be embedded in the first portion of the ring at a corresponding corner region of the ring. Specifically, each second portion of the ring may be disposed at an inner corner region of the ring, wherein the inner corner of the ring is also an inner corner of the corresponding L-shape, and wherein the inner corner of the L-shape refers to the juncture where the two arms of the L-shape meet (e.g., to form an angle of) 90°. The second material may have a second co-efficient of thermal expansion (CTE) that is smaller than the first co-efficient of thermal expansion (CTE). Advantageous features of such embodiments include allowing the tuning of a total co-efficient of thermal expansion (CTE) of the ring by adjusting for example, the shape, volume, and positions of the second portions of the ring. As a result, the total co-efficient of thermal expansion (CTE) of the ring can be optimized to minimize thermal stresses within the integrated circuit package in order to reduce a risk of warping of the package substrate. In addition, this optimization can also reduce thermal stresses at the interfaces of the integrated circuit package, resulting in a reduced risk of forming cracks or delamination. As a result, package reliability is improved.

In accordance with an embodiment, a method includes forming a redistribution structure over a carrier; attaching a semiconductor die to the redistribution structure using first conductive connectors; dispensing a first underfill into a first gap between the semiconductor die and the redistribution structure; bonding a substrate to the redistribution structure using second conductive connectors, the substrate being bonded to an opposing side of the redistribution structure as the semiconductor die; and attaching a ring to the substrate, where the ring surrounds the semiconductor die and the first underfill, and where the ring includes a first portion that includes a first material having a first co-efficient of thermal expansion; and second portions that include a second material having a second co-efficient of thermal expansion that is different from the first co-efficient of thermal expansion. In an embodiment, each of the second portions of the ring is disposed at a corresponding corner region of the ring. In an embodiment, each of the second portions of the ring is embedded in the first portion of the ring. In an embodiment, the first co-efficient of thermal expansion is greater than the second co-efficient of thermal expansion. In an embodiment, the first material includes copper and the second material includes aluminum. In an embodiment, the ring has a square-shape or a rectangular-shape when seen in a top-down view, and each of the second portions of the ring has a L-shape when seen in the top-down view. In an embodiment, the method further includes dispensing a second underfill into a second gap between the redistribution structure and the substrate.

In accordance with an embodiment, a method includes attaching a first die and a second die to a redistribution structure; forming a molding material to fill in a gap between adjacent sidewalls of the first die and the second die, where the molding material surrounds a perimeter of each of the first die and the second die; performing a singulation process to form a first package component and a second package component, the first package component including the first die and a first portion of the redistribution structure, and the second package component including the second die and a second portion of the redistribution structure; bonding a substrate to the first package component, the substrate being bonded to an opposing side of the first portion of the redistribution structure as the first die; and attaching a ring to the substrate, where the ring surrounds the first die and the first portion of the redistribution structure, and where the ring includes a first portion of the ring that includes a first material; and second portions of the ring that include a second material, the second material being different from the first material, where each of the second portions of the ring is disposed at a corresponding corner region of the ring. In an embodiment, each of the second portions of the ring have at least one sloping sidewall. In an embodiment, a width of each of the second portions of the ring decreases in a direction moving from a bottom surface of the second portion of the ring towards a top surface of the second portion of the ring. In an embodiment, attaching the ring to the substrate includes dispensing an adhesive material on the substrate; attaching the second portions of the ring to the substrate using the adhesive material; and after attaching the second portions of the ring to the substrate, attaching the first portion of the ring to the substrate using the adhesive material. In an embodiment, attaching the ring to the substrate includes dispensing an adhesive material on the substrate; attaching the first portion of the ring to the substrate using the adhesive material; and after attaching the first portion of the ring to the substrate, attaching the second portions of the ring to the substrate using the adhesive material. In an embodiment, the first material has a first co-efficient of thermal expansion, and the second material has a second co-efficient of thermal expansion, and where the first co-efficient of thermal expansion is greater than the second co-efficient of thermal expansion. In an embodiment, the first material includes copper and the second material includes aluminum. In an embodiment, the first co-efficient of thermal expansion is in a range from 16-20 ppm/° C., and the second co-efficient of thermal expansion is in a range from 8-14 ppm/° C.

In accordance with an embodiment, a semiconductor device includes a package component including a redistribution structure; and a first die coupled to the redistribution structure; a substrate coupled to the redistribution structure, where the redistribution structure is disposed between the first die and the substrate; a ring disposed over and coupled to the substrate, the ring surrounding the first die and the redistribution structure, and where the ring includes a first portion of the ring that includes a first material; and second portions of the ring that include a second material, the second material being different from the first material, where each of the second portions of the ring is disposed at a corresponding corner region of the ring. In an embodiment, the first portion of the ring extends over and is in physical contact with top surfaces of the second portions of the ring. In an embodiment, each of the second portions of the ring has an L-shape when seen in a top-down view. In an embodiment, the first material has a first co-efficient of thermal expansion, and the second material has a second co-efficient of thermal expansion, and where the first co-efficient of thermal expansion is greater than the second co-efficient of thermal expansion. In an embodiment, the first material includes copper, and the second material includes aluminum.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a redistribution structure over a carrier;
attaching a semiconductor die to the redistribution structure using first conductive connectors;
dispensing a first underfill into a first gap between the semiconductor die and the redistribution structure;
bonding a substrate to the redistribution structure using second conductive connectors, the substrate being bonded to an opposing side of the redistribution structure as the semiconductor die; and
attaching a ring to the substrate, wherein the ring surrounds the semiconductor die and the first underfill, and wherein the ring comprises:
a first portion that comprises a first material having a first co-efficient of thermal expansion; and
second portions that comprise a second material having a second co-efficient of thermal expansion that is different from the first co-efficient of thermal expansion.

2. The method of claim 1, wherein each of the second portions of the ring is disposed at a corresponding corner region of the ring.

3. The method of claim 2, wherein each of the second portions of the ring is embedded in the first portion of the ring.

4. The method of claim 3, wherein the first co-efficient of thermal expansion is greater than the second co-efficient of thermal expansion.

5. The method of claim 3, wherein the first material comprises copper and the second material comprises aluminum.

6. The method of claim 3, wherein the ring has a square-shape or a rectangular-shape when seen in a top-down view, and each of the second portions of the ring has a L-shape when seen in the top-down view.

7. The method of claim 3, further comprising:
dispensing a second underfill into a second gap between the redistribution structure and the substrate.

8. A method comprising:
attaching a first die and a second die to a redistribution structure;
forming a molding material to fill in a gap between adjacent sidewalls of the first die and the second die, wherein the molding material surrounds a perimeter of each of the first die and the second die;
performing a singulation process to form a first package component and a second package component, the first package component comprising the first die and a first portion of the redistribution structure, and the second package component comprising the second die and a second portion of the redistribution structure;
bonding a substrate to the first package component, the substrate being bonded to an opposing side of the first portion of the redistribution structure as the first die; and
attaching a ring to the substrate, wherein the ring surrounds the first die and the first portion of the redistribution structure, and wherein the ring comprises:
a first portion of the ring that comprises a first material; and
second portions of the ring that comprise a second material, the second material being different from the first material, wherein each of the second portions of the ring is disposed at a corresponding corner region of the ring.

9. The method of claim 8, wherein each of the second portions of the ring have at least one sloping sidewall.

10. The method of claim 9, wherein a width of each of the second portions of the ring decreases in a direction moving from a bottom surface of the second portion of the ring towards a top surface of the second portion of the ring.

11. The method of claim 8, wherein attaching the ring to the substrate comprises:
dispensing an adhesive material on the substrate;
attaching the second portions of the ring to the substrate using the adhesive material; and
after attaching the second portions of the ring to the substrate, attaching the first portion of the ring to the substrate using the adhesive material.

12. The method of claim 8, wherein attaching the ring to the substrate comprises:
dispensing an adhesive material on the substrate;
attaching the first portion of the ring to the substrate using the adhesive material; and
after attaching the first portion of the ring to the substrate, attaching the second portions of the ring to the substrate using the adhesive material.

13. The method of claim 8, wherein the first material has a first co-efficient of thermal expansion, and the second material has a second co-efficient of thermal expansion, and wherein the first co-efficient of thermal expansion is greater than the second co-efficient of thermal expansion.

14. The method of claim 13, wherein the first material comprises copper and the second material comprises aluminum.

15. The method of claim 13, wherein the first co-efficient of thermal expansion is in a range from 16-20 ppm/° C., and the second co-efficient of thermal expansion is in a range from 8-14 ppm/° C.

16. A semiconductor device comprising:
a package component comprising:
a redistribution structure; and
a first die coupled to the redistribution structure;
a substrate coupled to the redistribution structure, wherein the redistribution structure is disposed between the first die and the substrate;
a ring disposed over and coupled to the substrate, the ring surrounding the first die and the redistribution structure, and wherein the ring comprises:
a first portion of the ring that comprises a first material; and
second portions of the ring that comprise a second material, the second material being different from the first material, wherein each of the second portions of the ring is disposed at a corresponding corner region of the ring.

17. The semiconductor device of claim 16, wherein the first portion of the ring extends over and is in physical contact with top surfaces of the second portions of the ring.

18. The semiconductor device of claim 16, wherein each of the second portions of the ring has an L-shape when seen in a top-down view.

19. The semiconductor device of claim 16, wherein the first material has a first co-efficient of thermal expansion, and the second material has a second co-efficient of thermal expansion, and wherein the first co-efficient of thermal expansion is greater than the second co-efficient of thermal expansion.

20. The semiconductor device of claim 19, wherein the first material comprises copper, and the second material comprises aluminum.
